(19) United States
(12) Patent Application Publication
(10) Pub. No.: US 2024/0429219 A1
(43) Pub. Date: Dec. 26, 2024

(54) DISPLAY DEVICE AND TILED DISPLAY DEVICE INCLUDING THE SAME

(71) Applicant: Samsung Display Co., LTD., Yongin-si (KR)

(72) Inventors: Kyung Rock SON, Yongin-si (KR); Hui Won YANG, Yongin-si (KR); Gwang Geun LEE, Yongin-si (KR)

(21) Appl. No.: 18/657,654

(22) Filed: May 7, 2024

(30) Foreign Application Priority Data
Jun. 22, 2023 (KR) 10-2023-0080277

(51) Int. Cl. H01L 25/16; H01L 27/12

(52) U.S. Cl. CPC H01L 25/167; H01L 27/124

(57) ABSTRACT

A tiled display device includes a display device. The display device including a substrate, a plurality of transistors on one surface of the substrate, a plurality of light emitting elements on the plurality of transistors, a plurality of bottom wirings on a rear surface of the substrate, and a first selective reflective film between the substrate and the plurality of bottom wirings. The first selective reflective film includes M pairs of first layers and second layers, where M is an integer greater than or equal to 2. A refractive index of the first layer is higher than a refractive index of the second layer.

### CROSS-REFERENCE TO RELATED APPLICATION

The present application claims priority to and the benefit of Korean Patent Application No. 10-2023-0080277, filed on Jun. 22, 2023, in the Korean Intellectual Property Office, the entire disclosure of which is incorporated by reference herein.

### BACKGROUND

### 1. Field

One or more embodiments of the present disclosure relate to a display device and a tiled display device including the same.

### 2. Description of the Related Art

With the advance of information-oriented society, more and more demands are placed on display devices for displaying images in various ways. For example, a tiled display device including a plurality of display devices is being released as a product, and each of the plurality of display devices may be a flat panel display device such as a liquid crystal display, a field light emitting display and a light emitting display. A light emitting display device may include an organic light emitting display panel including an organic light emitting diode (OLED) element as a light emitting element, or a light emitting diode display panel including an inorganic light emitting diode element such as a light emitting diode (LED) as a light emitting element.

The display device includes a display area in which pixels displaying images are displayed and a non-display area (or bezel area) disposed around the display area and in which wires for driving the pixels are disposed. Recently, a bezel-less display device has been released to increase or maximize the area of the display area. Accordingly, there is an increasing demand for a display device capable of reducing the area of the non-display area or eliminating the non-display area by forming wires on the side surface of the substrate.

Bottom wirings such as data lines and power supply lines may be disposed on the rear surface of the display device to reduce or minimize the non-display area of the display device. However, characteristics of the thin film transistors (TFTs) may be changed by plasma in a process of patterning the bottom wirings, and accordingly, the bottom wirings may be recognized in an inspection process for inspecting the thin film transistors (TFTs) of the pixels.

### SUMMARY

Aspects and features of embodiments of the present disclosure provide a display device and a tiled display device capable of preventing bottom wirings from being recognized during an inspection process for inspecting thin film transistors of pixels.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, there is provide a display device including a substrate, a plurality of transistors on one surface of the substrate, a plurality of light emitting elements on the plurality of transistors, a plurality of bottom wirings on a rear surface of the substrate, and a first selective reflective film between the substrate and the plurality of bottom wirings. The first selective reflective film includes M pairs of first layers and second layers, where M is an integer greater than or equal to 2. A refractive index of the first layer is higher than a refractive index of the second layer.

A reflective target wavelength of the first selective reflective film may be 310 nm or less.

A difference between a refractive index of the first layer and a refractive index of the second layer may be 0.55 or more.

The first layer may be TiO₂, and the second layer may include SiO₂ or HfO₂.

The first layer may be Si₃N₄ and the second layer includes SiO₂.

A thickness of the first layer may be smaller than a thickness of the second layer.

The display device may further include a second selective reflective film between the substrate and the plurality of transistors. The second selective reflective film may include N pairs of a third layer and a fourth layer, where N is an integer greater than or equal to 2. A refractive index of the third layer may be higher than a refractive index of the fourth layer.

A reflective target wavelength of the second selective reflective film may be 310 nm or less.

A reflective target wavelength of the first selective reflective film may be substantially the same as a reflective target wavelength of the second selective reflective film.

A reflective target wavelength of the second selective reflective film may be smaller than a reflective target wavelength of the first selective reflective film.

A thickness of the second selective reflective film may be smaller than a thickness of the first selective reflective film.

The display device may further include a second selective reflective film between the substrate and the plurality of transistors. The second selective reflective film may include N pairs of a third layer and a fourth layer, where N is an integer greater than or equal to 2. A refractive index of the third layer may be higher than a refractive index of the fourth layer.

A reflective target wavelength of the second selective reflective film may be greater than a reflective target wavelength of the first selective reflective film.

A thickness of the second selective reflective film may be greater than a thickness of the first selective reflective film.

A thickness of the third layer may be greater than a thickness of the first layer, and a thickness of the fourth layer may be greater than a thickness of the third layer.

The display device may further include data lines on the one surface of the substrate, power supply lines on the one surface of the substrate, and side wirings on a side surface of the substrate, connected to one or more of the bottom wirings and the data lines, and connected to one or more of the bottom wirings and the power supply lines.

The display device may further include a device identifier on the rear surface of the substrate and separated from the bottom wirings.

According to one or more embodiments of the present disclosure, there is provide a display device including a substrate, a plurality of first transistors of a first sub-pixel and a plurality of second transistors of a second sub-pixel on one surface of the substrate, a first light emitting element on the plurality of first transistors of the first sub-pixel and a second light emitting element on the plurality of second transistors of the second sub-pixel, a plurality of bottom wirings on a rear surface of the substrate, and a first selective reflective film between the substrate and the plurality of bottom wirings. The first selective reflective film includes a first reflective film overlapping the plurality of first transistors of the first sub-pixel in a thickness direction of the substrate, and a second reflective film overlapping the plurality of second transistors of the second sub-pixel in the thickness direction of the substrate. The first reflective film and the second reflective film are apart from each other.

Each of the first reflective film and the second reflective film may include M pairs of first layers and second layers, where M may be an integer greater than or equal to 2. A refractive index of the first layer may be higher than a refractive index of the second layer.

According to one or more embodiments of the present disclosure, there is provide a tiled display device including a plurality of display devices, and a connection member between the plurality of display devices. One display device among the plurality of display devices includes a substrate, a plurality of transistors on one surface of the substrate, a plurality of light emitting elements on the plurality of transistors, a plurality of bottom wirings on a rear surface of the substrate, and a first selective reflective film between the substrate and the plurality of bottom wirings. The first selective reflective film includes M pairs of first layers and second layers, where M is an integer greater than or equal to 2. A refractive index of the first layer is higher than a refractive index of the second layer.

According to the aforementioned and other embodiments of the present disclosure, when the display panel includes the first selective reflective film that reflects short-wavelength light of 310 nm or less, incident of the short-wavelength light to the first to nineteenth channels of the first to nineteenth transistors of each of the sub-pixels may be prevented or reduced. Accordingly, it is possible to prevent or reduce the threshold voltages of the first to nineteenth transistors from being positively shifted by the short-wavelength light. Therefore, it is possible to minimize a difference in characteristics between the positive shifted transistor affected by the short-wavelength light and the positive-shifted transistor unaffected by the short-wavelength light. Accordingly, it is possible to reduce visibility of bottom wirings and device identifications in the current value image calculated in the inspection process.

According to the aforementioned and other embodiments of the present disclosure, because the second selective reflective film has the same target reflection wavelength as the first selective reflective film, the light of the first wavelength that has passed through the first selective reflective film without being reflected by the first selective reflective film may be reflected by the second selective reflective film. Therefore, it is possible to further prevent short-wavelength light of 310 nm or less from being incident on the first to nineteenth channels of the first to nineteenth transistors of each of the sub-pixels.

According to the aforementioned and other embodiments of the present disclosure, because the second selective reflective film has a target reflection wavelength different from that of the first selective reflective film, the light of a second wavelength that has passed through the first selective reflective film without being reflected by the first selective reflective film may be reflected by the second selective reflective film. Therefore, it is possible to further prevent short-wavelength light of 310 nm or less from being incident on the first to nineteenth channels of the first to nineteenth transistors of each of the sub-pixels.

According to the aforementioned and other embodiments of the present disclosure, because the second selective reflective film has a target reflection wavelength corresponding to the main peak wavelength of light emitted from the light emitting element, the light proceeding to the lower part of the light from the light-emitting element may be reflected to the upper part and emitted, so that the light-emitting efficiency of the light-emitting element may be increased.

### BRIEF DESCRIPTION OF DRAWINGS

The above and other embodiments and features of the present disclosure will become more apparent by describing embodiments thereof with reference to the attached drawings, in which:

FIGS. 1 and 2 are perspective views illustrating a display device according to one or more embodiments;

FIG. 3 is a layout view illustrating first to third sub-pixels of a pixel of a display device according to one or more embodiments;

FIG. 4 is a block view illustrating a display device according to one or more embodiments;

FIG. 5 is an equivalent circuit view illustrating a first sub-pixel according to one or more embodiments;

FIG. 6 is an equivalent circuit view illustrating a current path flowing through a first sub-pixel in an inspection process according to one or more embodiments;

FIG. 7 is a cross-sectional view illustrating one example of the first to fourth transistors and light emitting elements of the first sub-pixel according to one or more embodiments;

FIG. 8 is an enlarged cross-sectional view illustrating one example of the first selective reflective film of FIG. 7 in detail;

FIG. 9 is a table showing plasma wavelengths generated by different plasma gas used to pattern the bottom wiring shown in FIG. 2;

FIG. 10 is a table showing the first reflective metal layer and the second reflective metal layer and the thickness of the first reflective metal layer and the thickness of the second reflective metal layer calculated according to a first target wavelength shown in FIG. 8;

FIGS. 11 and 12 are current value images showing current values calculated by the inspection process in the presence and absence of the first selective reflective film;

FIG. 13 is a cross-sectional view illustrating an example of the first to fourth transistors of the first sub-pixel according to one or more embodiments;

FIG. 14 is an enlarged cross-sectional view illustrating one example of the second selective reflective film of FIG. 13 in detail;

FIG. 15 is a cross-sectional view illustrating one example of the first to fourth transistors of the first sub-pixel according to one or more embodiments;

FIG. 16 is a table showing the third reflective metal layer and the fourth reflective metal layer and the thickness of the third reflective metal layer and the thickness of the fourth reflective metal layer calculated according to a second target wavelength shown in FIG. 14;

FIG. 17 is a cross-sectional view illustrating an example of the first to fourth transistors of the first sub-pixel according to one or more embodiments;

FIG. 18 is an enlarged cross-sectional view illustrating one example of the second selective reflective film of FIG. 17;

FIG. 19 is a table showing the third reflective metal layer and the fourth reflective metal layer, and the thickness of the third reflective metal layer and the thickness of the fourth reflective metal layer calculated according to a third target wavelength shown in FIG. 17;

FIG. 20 is a cross-sectional view illustrating one example of the first and second transistors of the first sub-pixel and the first and second transistors of the second sub-pixel, according to one or more embodiments;

FIG. 21 is a perspective view illustrating a tiled display device including a plurality of display devices according to one or more embodiments;

FIG. 22 is an enlarged layout view illustrating a region W of FIG. 21 in detail.

FIG. 23 is a cross-sectional view illustrating an example of a tiled display device taken along the line N-N′ of FIG. 22.

### DETAILED DESCRIPTION

Aspects and features of embodiments of the present disclosure and methods of accomplishing the same may be understood more readily by reference to the detailed description of embodiments and the accompanying drawings.

Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected.

Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

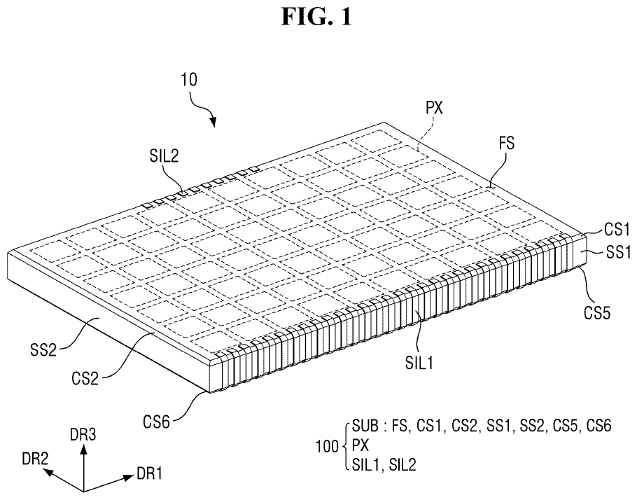

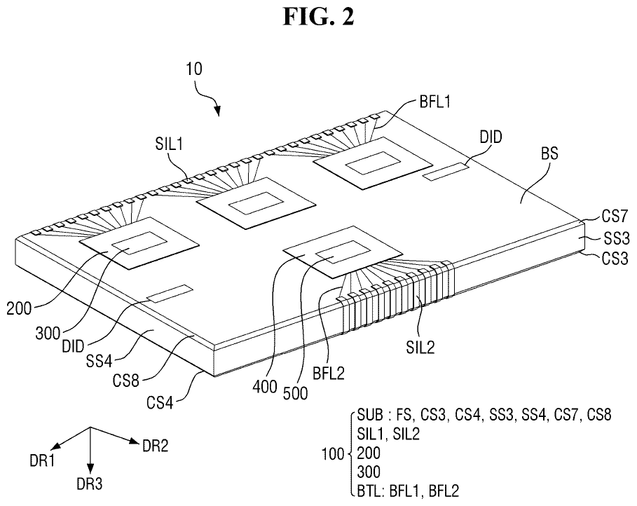

FIGS. 1 and 2 are perspective views illustrating a display device according to one or more embodiments.

Referring to FIGS. 1 and 2, a display device 10 is a device for displaying a moving image or a still image. The display device may be used as a display screen of various products such as televisions, laptop computers, monitors, billboards and the Internet of Things (IoT) as well as portable electronic devices such as mobile phones, smart phones, tablet personal computer (tablet PC), smart watches, watch phones, mobile communication terminals, electronic notebooks, electronic books, portable multimedia players (PMPs), navigation systems and ultra mobile PCs (UMPCs).

The display device 10 according to one or more embodiments may include a display panel 100, a circuit board 200, and a source driving circuit 300.

The display panel 100 includes a substrate SUB, bottom wirings BTL, a plurality of pixels PX, a plurality of first side wirings SIL1, a plurality of second side wirings SIL2, and a plurality of device identifiers DID. The bottom wirings BTL include first bottom fan-out wirings BFL1 and second bottom fan-out wirings BFL2.

The substrate SUB includes a first surface FS, a second surface BS, a plurality of chamfered surfaces CS1 to CS8, and a plurality of side surfaces SS1 to SS4.

The first surface FS may be the front surface of the substrate SUB. The first surface FS may have a rectangular shape having a long side in the first direction DR1 and a short side in the second direction DR2.

The second surface BS may be a surface opposite the first surface FS.

The second surface BS may be a rear surface of the substrate SUB. The second surface BS may have a rectangular shape having a long side in the first direction DR1 and a short side in the second direction DR2. The second surface BS may be a surface opposite the first surface FS.

The plurality of chamfered surfaces CS1 to CS8 refer to obliquely cut surfaces disposed between the first surface FS and the plurality of side surfaces SS1 to SS4 and between the second surface BS and the plurality of side surfaces SS1 to SS4 to prevent a chipping defect from occurring in the plurality of first side wirings SIL1 and the plurality of second side wirings SIL2. Because each of the plurality of first side wirings SIL1 and the plurality of second side wirings SIL2 may have a gentle bending angle due to the plurality of chamfered surfaces CS1 to CS8, chipping or cracking of the plurality of first side wirings SIL1 and the plurality of second side wirings SIL2 may be prevented.

The first chamfered surface CS1 may be extended from the first side of the first surface FS, for example, the lower side. The second chamfered surface CS2 may be extended from the second side of the first surface FS, for example, the left side. The third chamfered surface CS3 may be extended from the third side of the first surface FS, for example, the upper side. The fourth chamfered surface CS4 may be extended from the fourth side of the first surface FS, for example, the right side. An interior angle formed by the first surface FS and the first chamfered surface CS1, an interior angle formed by the first surface FS and the second chamfered surface CS2, an interior angle formed by the first surface FS and the third chamfered surface CS3, and an interior angle formed by the first surface FS and the fourth chamfered surface CS4 may be greater than 90 degrees.

The fifth chamfered surface CS5 may be extended from the first side of the second surface BS, for example, the lower side. The sixth chamfered surface CS6 may be extended from the second side of the second surface BS, for example, the left side. The seventh chamfered surface CS7 may be extended from the third side of the second surface BS, for example, the upper side. The eighth chamfered surface CS8 may be extended from the fourth side of the second surface BS, for example, the right side. An interior angle formed by the second surface BS and the fifth chamfered surface CS5, an interior angle formed by the second surface BS and the sixth chamfered surface CS6, an interior angle formed by the second surface BS and the seventh chamfered surface CS7, and an interior angle formed by the second surface BS and the eighth chamfered surface CS8 may be greater than 90 degrees.

The first side surface SS1 may be extended from the first chamfered surface CS1. The first chamfered surface CS1 may be disposed between the first surface FS and the first side surface SS1. The first side surface SS1 may be a lower surface of the substrate SUB.

The second side surface SS2 may be extended from the second chamfered surface CS2. The second chamfered surface CS2 may be disposed between the first surface FS and the second side surface SS2. The second side surface SS2 may be the left side of the substrate SUB.

The third side surface SS3 may be extended from the third chamfered surface CS3. The third chamfered surface CS3 may be disposed between the first surface FS and the third side surface SS3. The third side surface SS3 may be an upper surface of the substrate SUB.

The fourth side surface SS4 may be extended from the fourth chamfered surface CS4. The fourth chamfered surface CS4 may be disposed between the first surface FS and the fourth side surface SS4. The fourth side surface SS4 may be the right side of the substrate SUB.

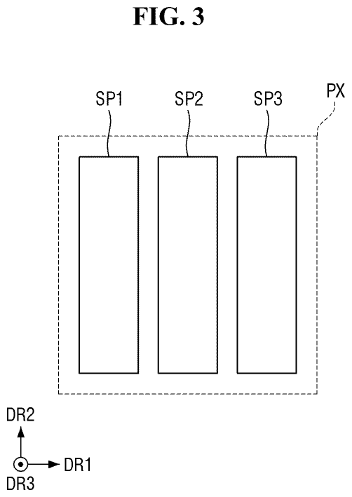

The plurality of pixels PX may be disposed on the first surface FS of the substrate SUB to display an image. The plurality of pixels PX may be arranged in a matrix form in the first and second directions DR1 and DR2. For example, the plurality of pixels PX may be arranged along rows and columns of a matrix along the first and second directions DR1 and DR2. A description of the plurality of pixels PX will be described later with reference to FIG. 3.

The plurality of first side wirings SIL1 may be disposed on at least one side surface of at least two chamfered surfaces from among the first surface FS, the second surface BS, and the plurality of chamfered surfaces CS1 to CS8 and may be disposed on at least one of the plurality of side surfaces SS1 to SS4. For example, the plurality of first side wirings SIL1 may be disposed on the first surface FS, the second surface BS, the first chamfered surface CS1, the fifth chamfered surface CS5, and the first side surface SS1 to connect the first pads disposed on the first side of the first surface FS and the first bottom fan-out wirings BFL1 of the second surface BS.

The plurality of second side wirings SIL2 may be disposed on at least one side surface of at least two chamfered surfaces from among the first surface FS, the second surface BS, and the plurality of chamfered surfaces CS1 to CS8 and may be disposed on at least one of the plurality of side surfaces SS1 to SS4. For example, the plurality of second side wirings SIL2 may be disposed on the first surface FS, the second surface BS, the third chamfered surface CS3, the seventh chamfered surface CS7, and the third side surface SS3 to connect the second pads disposed on the second side opposite to the first side of the first surface FS and the second bottom fan-out wirings BFL2 of the second surface BS.

Each of the plurality of first side wirings SIL1 connects the first pads disposed on the first surface FS and the first bottom fan-out wirings BFL1 disposed on the second surface BS. Each of the plurality of second side wirings SIL2 connects the second pads disposed on the first surface FS and the second bottom fan-out wirings BFL2 disposed on the second surface BS. The first pads and the second pads may correspond to front pads. The first pads may be connected to data lines connected to the pixels PX of the substrate SUB. Some of the second pads may be connected to the first power supply line disposed on the first surface FS of the substrate SUB, and another part may be connected to the global power supply line disposed on the first surface FS of the substrate SUB.

Each of the plurality of device identifiers DID may be an identification such as an identification number assigned to each display device 10 to distinguish the display device 10. The plurality of device identifiers DID may be disposed on the second surface BS of the substrate SUB. When viewed on a plane, the plurality of device identifiers DID may be disposed apart (e.g., spaced) from the first back fan-out wirings BFL1, the second bottom fan-out wirings BFL2, the plurality of first side wirings SIL1, and the plurality of second side wirings SIL2. Also, the plurality of device identifiers DID may be disposed apart (e.g., spaced) from the plurality of first circuit boards 200 and the second circuit board 400 when viewed on the plane. That is, the plurality of device identifiers DID may be in an electrically floating state.

Some of the plurality of device identifiers DID may be disposed adjacent to the sixth chamfered surface CS6 and others may be disposed adjacent to the eighth chamfered surface CS8. Some of the plurality of device identifiers DID may be disposed closer to the fifth chamfer surface CS5 than others. Also, some of the plurality of device identifiers DID may be disposed adjacent to the seventh chamfer surface CS7 compared to some above.

The plurality of device identifiers DID may be a rear metal layer formed of the same material as the first back fan-out wirings BFL1 and the second bottom fan-out wirings BFL2 by the same process. For example, the rear metal layer may be formed as a single layer or multiple layers made of at least one of molybdenum (Mo), aluminum (Al), chromium (Cr), gold (Au), titanium (Ti), nickel (Ni), neodymium (Nd) and/or copper (Cu) and/or an alloy thereof.

A plurality of first circuit boards 200 may be disposed on the second surface BS of the substrate SUB. Each of the plurality of first circuit boards 200 may be connected to the first bottom fan-out wirings BFL1 disposed on the second surface BS of the substrate SUB by using a conductive adhesive member such as an anisotropic conductive film. The plurality of first circuit boards 200 may be electrically connected to the plurality of first side wirings SIL1 through the first bottom fan-out wirings BFL1. The plurality of first circuit boards 200 may be flexible printed circuit boards, printed circuit boards, and/or flexible films.

A second circuit board 400 may be disposed on the second surface BS of the substrate SUB. The second circuit board 400 may be connected to the second bottom fan-out wirings BFL2 disposed on the second surface BS of the substrate SUB by using the conductive adhesive member. The second circuit board 400 may be electrically connected to the plurality of second side wirings SIL2 through the second bottom fan-out wirings BFL2. The second circuit board 400 may be the flexible printed circuit board, the printed circuit board, or the flexible film.

Each of the source driving circuits 300 may generate data voltages and supply the generated data voltages to data lines through the first circuit board 200, the first bottom fan-out wirings BFL1, and the plurality of first side wirings SIL1. Each of the source driving circuits 300 may be formed as an integrated circuit (IC) and attached to a corresponding circuit board 200. Alternatively, the source driving circuit 300 may be directly attached to the second surface BS of the substrate SUB using a chip on glass (COG) method.

A power supply circuit 500 may generate and supply suitable voltages (e.g., predetermined voltages) to suitable voltage lines (e.g., predetermined voltage lines) through the second circuit board 400, the second bottom fan-out wirings BFL2, and the plurality of second side wirings SIL2. For example, the power supply circuit 500 may generate a first power voltage and supply it to the first power line through the second circuit board 400, the second bottom fan-out wirings BFL2, and the plurality of second side wirings SIL2. In addition, the power supply circuit 500 may generate a global power voltage GV and supply it to the global power line through the second circuit board 400, the second bottom fan-out wirings BFL2, and the plurality of second side wirings SIL2. The power supply circuit 500 may be formed as the integrated circuit (IC) and attached to the second circuit board 400. Alternatively, the power supply circuit 500 may be directly attached to the second surface BS of the substrate SUB using the chip on glass (COG) method.

As shown in FIGS. 1 and 2, the flexible film bent along the side surface of the substrate SUB may be removed by using the plurality of first side wirings SIL1 and the plurality of second side wirings SIL2. As a result, a bezel-less display device may be implemented.

FIG. 3 is a layout diagram illustrating first to third sub-pixels of a pixel of a display device according to one or more embodiments.

Referring to FIG. 3, each of the pixels PX may include a plurality of sub-pixels SP1, SP2, and SP3. In FIG. 3, it is shown that each of the pixels PX includes three sub-pixels SP1, SP2, and SP3, that is, a first sub-pixel SP1, a second sub-pixel SP2, and a third sub-pixel SP3 but the present disclosure is not limited thereto. Each of the first sub-pixel SP1, the second sub-pixel SP2, and the third sub-pixel SP3 may be connected to at least one of the PWM data lines DL, at least one of the first to third data lines RDL, GDL, and BDL, and at least one of the scan lines GWL, GIL, GCL, SWPL, PAEL, and PWEL.

Each of the first sub-pixel SP1, the second sub-pixel SP2, and the third sub-pixel SP3 may have a rectangular, square, or rhombus planar shape. For example, each of the first sub-pixel SP1, the second sub-pixel SP2, and the third sub-pixel SP3 may have a rectangular planar shape having a short side in the first direction DR1 and a long side in the second direction DR2. Alternatively, each of the first sub-pixel SP1, the second sub-pixel SP2, and the third sub-pixel SP3 may have a planar shape of a square or rhombus including sides having the same length in the first direction DR1 and the second direction DR2.

As shown in FIG. 3, the first sub-pixel SP1, the second sub-pixel SP2, and the third sub-pixel SP3 may be arranged along the first direction DR1. Alternatively, one of the second sub-pixel SP2 and the third sub-pixel SP3 and the first sub-pixel SP1 may be arranged along the first direction DR1, and the other one and the first sub-pixel SP1 may be arranged along the second direction DR2. For example, the first sub-pixel SP1 and the second sub-pixel SP2 may be arranged along the first direction DR1, and the first sub-pixel SP1 and the third sub-pixel SP3 may be arranged along the second direction DR2. Alternatively, one of the first sub-pixel SP1 and the third sub-pixel SP3 and the second sub-pixel SP2 may be arranged along the first direction DR1, and the other one and the third sub-pixel SP3 may be arranged along the second direction DR2.

The first sub-pixel SP1 may emit first light, the second sub-pixel SP2 may emit second light, and the third sub-pixel SP3 may emit third light. Here, the first light may be light in a red wavelength band, the second light may be light in a green wavelength band, and the third light may be light in a blue wavelength band. The red wavelength band may be a wavelength band of approximately 600 nm to 750 nm, the green wavelength band may be a wavelength band of approximately 480 nm to 560 nm, and the blue wavelength band may be a wavelength band of approximately 370 nm to 460 nm, but the present disclosure is not limited thereto.

Each of the first sub-pixel SP1, the second sub-pixel SP2, and the third sub-pixel SP3 may include an inorganic light emitting element having an inorganic semiconductor as a light emitting element emitting light. For example, the inorganic light emitting element may be a flip chip type micro light emitting diode (LED), but the present disclosure is not limited thereto.

As shown in FIG. 3, the area of the first sub-pixel SP1, the area of the second sub-pixel SP2, and the area of the third sub-pixel SP3 may be substantially the same, but the present disclosure is not limited thereto. At least one of the area of the first sub-pixel SP1, the area of the second sub-pixel SP2, and the area of the third sub-pixel SP3 may be different from the other one. Alternatively, any two of the area of the first sub-pixel SP1, the area of the second sub-pixel SP2, and the area of the third sub-pixel SP3 may be substantially the same and the other one may be different from the above two. Alternatively, the area of the first sub-pixel SP1, the area of the second sub-pixel SP2, and the area of the third sub-pixel SP3 may be different from each other.

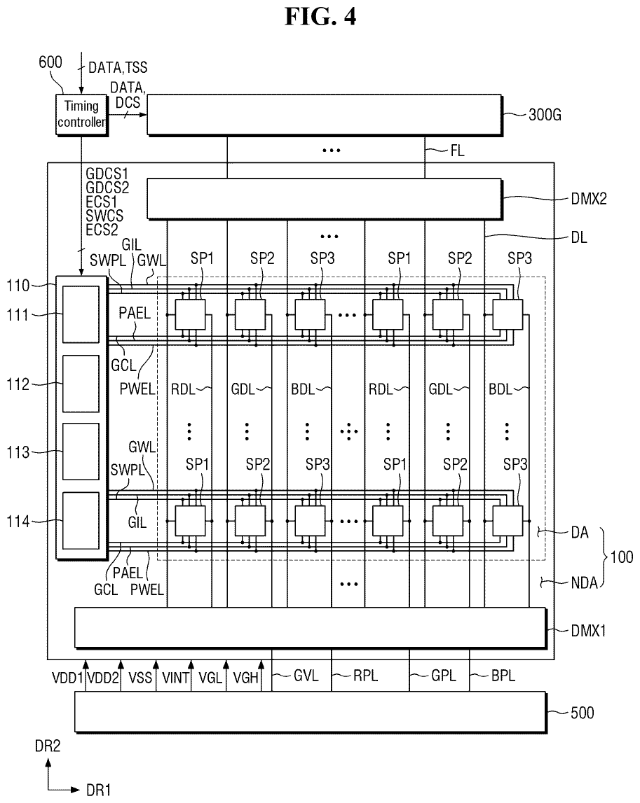

FIG. 4 is a block diagram illustrating a display device according to one or more embodiments.

Referring to FIG. 4, the display device 10 includes a display panel 100, a scan driving circuit 110, a data driving circuit 300G, a timing control circuit 600, and a power supply circuit 500.

A display area DA of the display panel 100 may include sub-pixels SP1, SP2, and SP3 displaying an image, scan write lines GWL connected to the sub-pixels SP1, SP2, and SP3, scan initialization lines GIL, scan control lines GCL, sweep signal lines SWPL, PWM light emitting lines PWEL, PAM light emitting lines PAEL, PWM data lines DL, first data lines RDL, second data lines GDL, and third data lines BDL.

The scan write lines GWL, scan initialization lines GIL, scan control lines GCL, sweep signal lines SWPL, PWM light emitting lines PWEL, and PAM light emitting lines PAEL may be extended in the first direction DR1 (X-axis direction) and may be arranged along the second direction DR2 (Y-axis direction) crossing the first direction DR1 (X-axis direction). The PWM data lines DL, the first data lines RDL, the second data lines GDL, and the third data lines BDL may be extended in the second direction DR2 (Y-axis direction) and may be arranged along the first direction DR1 (X-axis direction). The first data lines RDL may be electrically connected to each other, the second data lines GDL may be electrically connected to each other, and the third data lines BDL may be electrically connected to each other.

The sub-pixels SP1, SP2, and SP3 may include first sub-pixels SP1 emitting a first light, second sub-pixels SP2 emitting a second light, and third sub-pixels SP3 emitting a third light. The first light indicates light in a red wavelength band, the second light indicates light in a green wavelength band, and the third light indicates light in a blue wavelength band. For example, the main peak wavelength of the first light may be located in a range of approximately 600 nm to approximately 750 nm, the main peak wavelength of the second light may be located in a range of approximately 480 nm to approximately 560 nm, and the main peak wavelength of the third light may be located in a range of approximately 370 nm to approximately 460 nm.

Each of the sub-pixels SP1, SP2, and SP3 may be connected to one of the scan write lines GWL, one of the scan initialization lines GIL, one of the scan control lines GCL, one of the sweep signal lines SWPL, one of the PWM light emitting lines PWEL, and one of the PAM light emitting lines PAEL. Also, each of the first sub-pixels SP1 may be connected to one of the PWM data lines DL and one of the first data lines RDL. Also, each of the second sub-pixels SP2 may be connected to one of the PWM data lines DL and one of the second data lines GDL. Also, each of the third sub-pixels SP3 may be connected to one of the PWM data lines DL and one of the third data lines BDL.

A non-display area NDA of the display panel 100 may include a scan driving circuit 110, a first demultiplexer DMX1, and a second demultiplexer DMX2.

The scan driving circuit 110 may be disposed on the display panel 100 to apply signals to scan write lines GWL, scan initialization lines GIL, scan control lines GCL, sweep signal lines SWPL, the PWM light emitting lines PWEL, and the PAM light emitting lines PAEL. FIG. 1 illustrates that the scan driving circuit 110 is disposed at one edge of the display panel 100 but is not limited thereto. The scan driving circuit 110 may be disposed on both edges of the display panel 100.

The scan driving circuit 110 may include a first scan signal driving circuit 111, a second scan signal driving circuit 112, a sweep signal driving circuit 113, and a light emitting signal driving circuit 114.

The first scan signal driving circuit 111 may receive a first scan driving control signal GDCS1 from the timing control circuit 600. The first scan signal driving circuit 111 may output scan initialization signals to scan initialization lines GIL and scan write signals to scan write lines GWL according to the first scan driving control signal GDCS1. That is, the first scan signal driving circuit 111 may output two scan signals, that is, scan initialization signals and scan write signals together.

The second scan signal driving circuit 112 may receive the second scan driving control signal GDCS2 from the timing control circuit 600. The second scan signal driving circuit 112 may output scan control signals to the scan control lines GCL according to the second scan driving control signal GDCS2.

The sweep signal driving circuit 113 may receive a first emitting control signal ECS1 and a sweep control signal SWCS from the timing control circuit 600. The sweep signal driving circuit 113 may output PWM light emitting signals to the PWM light emitting lines PWEL and output sweep signals to the sweep signal lines SWPL according to the first emitting control signal ECS1. That is, the sweep signal driving circuit 113 may output PWM light emitting signals and sweep signals together.

The emitting signal driving circuit 114 may receive a second emitting control signal ECS2 from the timing control circuit 600. The light emitting signal driving circuit 114 may output PAM light emitting signals to the PAM light emitting lines PAEL according to the second light emitting control signal ECS2.

The first demultiplexer DMX1 switches the connection between each PWM data line DL and the global power line GVL. In addition, the first demultiplexer DMX1 switches the connection between each first data line RDL and a first data voltage line RPL, switches the connection between each second data line GDL and the second data voltage line GPL, and switches the connection between each third data line BDL and the third data voltage line BPL.

The second demultiplexer DMX2 may be disposed between the fan-out wirings FL and the PWM data lines DL. The second demultiplexer DMX2 may distribute the PWM data voltages applied to each fan-out line FL to Q (Q is an integer greater than or equal to 2) PWM data lines DL or Q first to third data lines RDL, GDL, and BDL.

The first demultiplexer DMX1 may be disposed adjacent to the second pads, and the second demux unit DMX2 may be disposed adjacent to the first pads. That is, the first demultiplexer DMX1 may be disposed adjacent to one side of the display panel 100, for example, a lower side of the display panel 100. The second demultiplexer DMX2 may be disposed adjacent to the other side of the display panel 100, for example, an upper side of the display panel 100.

The timing control circuit 600 receives digital video data DATA and timing signals TSS. The timing control circuit 600 may generate the first scan driving control signal GDCS1, a second scan driving control signal GDSC2, the first light emitting control signal ECS1, the second light emitting control signal ECS2, and a sweep control signal SWCS for controlling the operation timing of the scan driving circuit 110 according to the timing signals TSS. Also, the timing control circuit 600 may generate a source control signal DCS for controlling the operation timing of the data driving circuit 300G.

The timing control circuit 600 outputs the first scan driving control signal GDCS1, the second scan driving control signal GDCS2, the first emitting control signal ECS1, the second emitting control signal ECS2, and the sweep control signal SWCS to the scan driving circuit 110. The timing control circuit 600 outputs the digital video data DATA and the source control signal DCS to the data driving circuit 300G.

The data driving circuit 300G may include a plurality of source driving circuits 300. The data driving circuit 300G converts the digital video data DATA into analog PWM data voltages and outputs them to the fan-out wirings FL.

The power supply circuit 500 may generate and output a first data voltage to the first data voltage line RPL, may generate and output a second data voltage to the second data voltage line GPL, and may generate and output a third data voltage to the third data voltage line BPL. The power supply circuit 500 may generate and output the global power voltage GV to the global power line GVL.

In addition, the power supply circuit 500 may generate and output a plurality of power voltages to the display panel 100. For example, the power supply circuit 500 may output a first power voltage VDD1, a second power supply voltage VDD2, a third power voltage VSS, an initialization voltage VINT, a gate-on voltage VGL, and a gate-off voltage VGH to the display panel 100. The first power voltage VDD1 and the second power supply voltage VDD2 may be high potential driving voltages for driving light emitting elements of each of the sub-pixels SP1, SP2, and SP3. The third power voltage VSS may be a low potential driving voltage for driving light emitting elements of each of the sub-pixels SP1, SP2, and SP3. The initialization voltage VINT and the gate-off voltage VGH are applied to each of the sub-pixels SP1, SP2, and SP3, and the gate-on voltage VGL and the gate-off voltage VGH may be applied to the scan driving circuit 110.

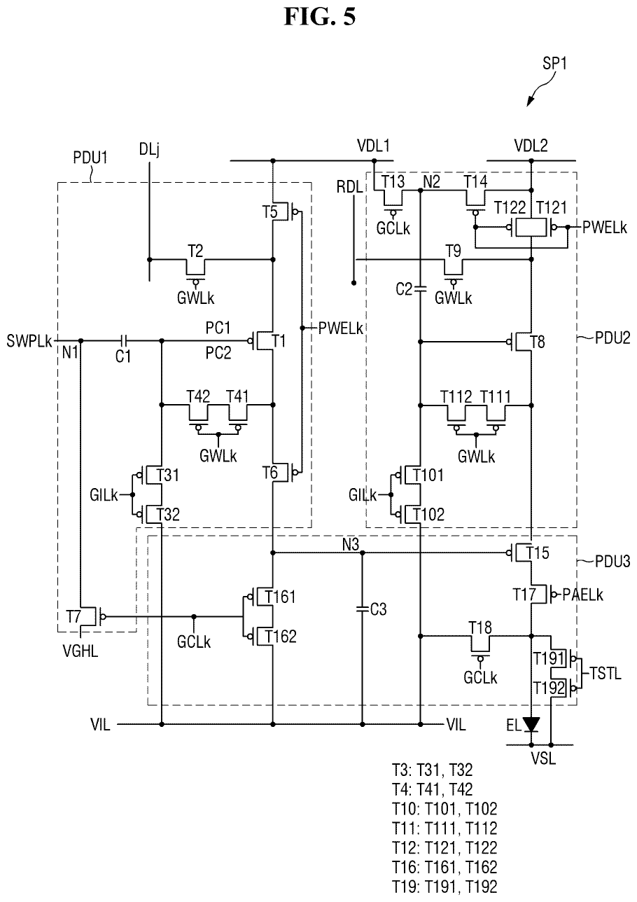

FIG. 5 is an equivalent circuit diagram illustrating a first sub-pixel according to one or more embodiments.

Referring to FIG. 5, the first sub-pixel SP1 according to one or more embodiments may be connected to a k^{th} scan write line GWLk, a k^{th} scan initialization line GILk, a k^{th} scan control line GCLk, a k^{th} sweep signal line SWPLk, a k^{th} PWM light emitting line PWELk, and a k^{th} PAM light emitting line PAELk. Also, the first sub-pixel SP1 may be connected to the j^{th} PWM data line DLj and the first data line RDL. In addition, the first sub-pixel SP1 may be connected to a first power supply line VDL1 to which the first power voltage VDD1 is applied, the second power supply line VDL2 to which the second power supply voltage VDD2 is applied, a third power supply line VSL to which a third power supply voltage VSS is applied, an initialization voltage line VIL to which an initialization voltage VINT is applied, and a gate-off voltage line VGHL to which the gate-off voltage VGH is applied. Meanwhile, the j^{th} PWM data line DLj may be referred to as a first data line, and the first data line RDL may be referred to as a second data line for convenience of description.

The first sub-pixel SP1 may include a light emitting element EL, a first pixel driving unit PDU1, a second pixel driving unit PDU2, and a third pixel driving unit PDU3.

The light emitting element EL emits light according to a driving current generated by the second pixel driving unit PDU2. The light emitting element EL may be disposed between the seventeenth transistor T17 and the third power supply line VSL. A first electrode of the light emitting element EL may be connected to the second electrode of the seventeenth transistor T17 and the second electrode may be connected to the third power supply line VSL. The first electrode of the light emitting element EL may be an anode electrode, and the second electrode may be a cathode electrode. A light emitting element EL may be an inorganic light emitting element including the first electrode, the second electrode, and the inorganic semiconductor disposed between the first electrode and the second electrode. For example, the light emitting element EL may be a micro light emitting diode formed of the inorganic semiconductor but is not limited thereto.

The first pixel driving unit PDU1 generates a control current according to the j^{th} PWM data voltage of the j^{th} PWM data line DLj to control a voltage of a third node N3 of the third pixel driving unit PDU3. Because a pulse width of the first driving current flowing through the light emitting element EL may be adjusted by the control current of the first pixel driving unit PDU1, the first pixel driving unit PDU1 may be a pulse width modulation PWM unit for performing pulse width modulation of the first driving current flowing through the light emitting element EL.

The first pixel driving unit PDU1 may include the first to seventh transistors T1 to T7 and a first capacitor C1.

The first transistor T1 controls the control current flowing between the first electrode and the second electrode of the first transistor T1 according to the PWM data voltage applied to a gate electrode.

The second transistor T2 is turned-on by a k^{th} scan write signal of a k^{th} scan write line GWLk to supply the PWM data voltage of the j^{th} PWM data line DLj to the first electrode of the first transistor T1. The gate electrode of the second transistor T2 may be connected to the k^{th} scan write line GWLk, the first electrode may be connected to the j^{th} PWM data line DLj, and the second electrode may be connected to the first electrode of the first transistor T1.

The third transistor T3 is turned-on by a k^{th} scan initialization signal of the k^{th} scan initialization line GILk to connect the initialization voltage line VIL to the gate electrode of the first transistor T1. In this case, the gate-on voltage VGL of the k^{th} scan initialization signal may be different from the initialization voltage VINT of the initialization voltage line VIL. In particular, because the difference voltage between the gate-on voltage VGL and the initialization voltage VINT is greater than the threshold voltage of the third transistor T3, the third transistor T3 may be stably turned-on even after the initialization voltage VINT is applied to the gate electrode of the first transistor T1. Accordingly, when the third transistor T3 is turned-on, the initialization voltage VINT may be stably applied to the gate electrode of the first transistor T1 regardless of the threshold voltage of the third transistor T3.

The third transistor T3 may include a plurality of transistors connected in series. For example, the third transistor T3 may include a first sub-transistor T31 and a second sub-transistor T32. Accordingly, it is possible to prevent the voltage of the gate electrode of the first transistor T1 from leaking through the third transistor T3. The gate electrode of the first sub-transistor T31 may be connected to the k^{th} scan initialization line GILk, the first electrode may be connected to the gate electrode of the first transistor T1, and the second electrode may be connected to the first electrode of the second sub-transistor T32. The gate electrode of the second sub-transistor T32 may be connected to the k^{th} scan initialization line GILk, the first electrode may be connected to the second electrode of the first sub-transistor T31, and the second electrode may be connected to the initialization voltage line VIL.

The fourth transistor T4 is turned-on by the k^{th} scan write signal of the k^{th} scan write line GWLk to connect the gate electrode to the second electrode of the first transistor T1. Accordingly, the first transistor T1 may operate as a diode while the fourth transistor T4 is turned-on (e.g., the first transistor T1 may be diode-connected).

The fourth transistor T4 may include the plurality of transistors connected in series. For example, the fourth transistor T4 may include a third sub-transistor T41 and a fourth sub-transistor T42. Accordingly, it is possible to prevent the voltage of the gate electrode of the first transistor T1 from leaking through the fourth transistor T4. The gate electrode of the third sub-transistor T41 may be connected to the k^{th} scan write line GWLk, the first electrode may be connected to the second electrode of the first transistor T1, and the second electrode may be connected to the first electrode of the fourth sub transistor T42. The gate electrode of the fourth sub-transistor T42 may be connected to the k^{th} scan write line GWLk, the first electrode may be connected to the second electrode of the third sub-transistor T41, and the second electrode may be connected to the gate electrode of the first transistor T1.

The fifth transistor T5 is turned-on by the k^{th} PWM light emitting signal of the k^{th} PWM light emitting line PWELk to connect the first electrode of the first transistor T1 to the first power supply line VDL1. The gate electrode of the fifth transistor T5 may be connected to the k^{th} PWM light emitting line PWELk, the first electrode may be connected to the first power supply line VDL1, and the second electrode may be connected to the first electrode of the first transistor T1.

The sixth transistor T6 is turned-on by the k^{th} PWM light emitting signal of the k^{th} PWM light emitting line PWELk to connect the second electrode of the first transistor T1 to the third node of the third pixel driving unit PDU3. The gate electrode of the sixth transistor T6 may be connected to the k^{th} PWM light emitting line PWELk, the first electrode may be connected to the second electrode of the first transistor T1, and the second electrode may be connected to the third node N3 of the third pixel driving unit PDU3.

The seventh transistor T7 is turned-on by the k^{th} scan control signal of the k^{th} scan control line GCLk to supply the gate-off voltage VGH of the gate-off voltage line VGHL to the first node N1 connected to the k^{th} sweep signal line SWPLk. Accordingly, a voltage change of the gate electrode of the first transistor T1 may be prevented from being reflected to the k^{th} sweep signal of the k^{th} sweep signal line SWPLk by the first capacitor C1 during the period in which the initialization voltage VINT is applied to the gate electrode of the first transistor T1 and the period in which the PWM data voltage of the j^{th} PWM data line DLj and the threshold voltage Vth1 of the first transistor T1 are programmed. The gate electrode of the seventh transistor T7 may be connected to the k^{th} scan control line GCLk, the first electrode may be connected to the gate-off voltage line VGHL, and the second electrode may be connected to the first node N1.

The first capacitor C1 may be disposed between the gate electrode of the first transistor T1 and the first node N1. One electrode of the first capacitor C1 may be connected to the gate electrode of the first transistor T1, and the other electrode may be connected to the first node N1.

The first node N1 may be a contact point of the k^{th} sweep signal line SWPLk, the second electrode of the seventh transistor T7, and the other electrode of the first capacitor C1.

The second pixel driving unit PDU2 generates the driving current applied to the light emitting element EL according to the first PWM data voltage of the first data line RDL. The second pixel driving unit PDU2 may be a pulse amplitude modulation unit (PAM unit) that performs pulse amplitude modulation. The second pixel driving unit PDU2 may be a constant current generator generating a constant driving current according to the first PWM data voltage.

In addition, the second pixel driving unit PDU2 of each of the first sub-pixels SP1 may receive the same first PWM data voltage and generate the same driving current regardless of the luminance of the first sub-pixel SP1. Similarly, the second pixel driving unit PDU2 of each of the second sub-pixels SP2 may receive the same second PWM data voltage and generate the same driving current regardless of the luminance of the second sub-pixel SP2. The third pixel driving unit PDU3 of each of the third sub-pixels SP3 may receive the same third PWM data voltage and generate the same driving current regardless of the luminance of the third sub-pixel SP3.

The second pixel driving unit PDU2 may include eighth to fourteenth transistors T8 to T14 and a second capacitor C2.

The eighth transistor T8 controls the driving current flowing to the light emitting element EL according to the voltage applied to the gate electrode of the eighth transistor T8.

The ninth transistor T9 is turned-on by a k^{th} scan write signal of a k^{th} scan write line GWLk to supply the first PWM data voltage of the first data line RDL to the first electrode of the eighth transistor T8. The gate electrode of the eighth transistor T8 may be connected to the k^{th} scan write line GWLk, the first electrode may be connected to the first data line RDL, and the second electrode may be connected to the first electrode of the eighth transistor T8.

The tenth transistor T10 is turned-on by a k^{th} scan initialization signal of a k^{th} scan initialization line GILk to connect the initialization voltage line VIL to the gate electrode of the eighth transistor T8. Accordingly, the gate electrode of the eighth transistor T8 may be discharged to the initialization voltage VINT of the initialization voltage line VIL during the turned-on period of the tenth transistor T10. In this case, the gate-on voltage VGL of the k^{th} scan initialization signal may be different from the initialization voltage VINT of the initialization voltage line VIL. Especially, since the difference voltage between the gate-on voltage VGL and the initialization voltage VINT is greater than the threshold voltage of the tenth transistor T10, the tenth transistor T10 may be stably turned-on even after the initialization voltage VINT is applied to the gate electrode of the eighth transistor T8. Accordingly, when the tenth transistor T10 is turned-on, the initialization voltage VINT may be stably applied to the gate electrode of the eighth transistor T8 regardless of the threshold voltage of the tenth transistor T10.

The tenth transistor T10 may include the plurality of transistors connected in series. For example, the tenth transistor T10 may include a fifth sub-transistor T101 and a sixth sub-transistor T102. Accordingly, it is possible to prevent the voltage of the gate electrode of the eighth transistor T8 from leaking through the tenth transistor T10. The gate electrode of the fifth sub-transistor T101 may be connected to the k^{th} scan initialization line GILk, the first electrode may be connected to the gate electrode of the eighth transistor T8, and the second electrode may be connected to the first electrode of the sixth sub transistor T102. The gate electrode of the sixth sub-transistor T102 may be connected to the k^{th} scan initialization line GILk, the first electrode may be connected to the second electrode of the fifth sub-transistor T101, and the second electrode may be connected to the initialization voltage line VIL.

The eleventh transistor T11 is turned-on by the k^{th} scan write signal of the k^{th} scan write line GWLk and connects the gate electrode to the second electrode of the eighth transistor T8. Accordingly, the eighth transistor T8 may operate as a diode while the eleventh transistor T11 is turned-on (e.g., the eighth transistor T8 is diode-connected).

The eleventh transistor T11 may include the plurality of transistors connected in series. For example, the eleventh transistor T11 may include a seventh sub-transistor T111 and an eighth sub-transistor T112. Accordingly, it is possible to prevent the voltage of the gate electrode of the eighth transistor T8 from leaking through the eleventh transistor T11. The gate electrode of the seventh sub-transistor T111 may be connected to the k^{th} scan write line GWLk, the first electrode may be connected to the second electrode of the eighth transistor T8, and the second electrode may be connected to the first electrode of the eighth sub transistor T112. The gate electrode of the eighth sub-transistor T112 may be connected to the k^{th} scan write line GWLk, the first electrode may be connected to the second electrode of the seventh sub-transistor T111, and the second electrode may be connected to the gate electrode of the eighth transistor T8.

The twelfth transistor T12 is turned-on by the k^{th} PWM light emitting signal of the k^{th} PWM light emitting line PWELk to connect the first electrode of the eighth transistor T8 to the second power supply line VDL2. The gate electrode of the twelfth transistor T12 may be connected to the k^{th} PWM light emitting line PWELk, the first electrode may be connected to the second power supply line VDL2, and the second electrode may be connected to the first electrode of the eighth transistor T8.

The twelfth transistor T12 may include a plurality of transistors connected in series. For example, the twelfth transistor T12 may include a nineth sub-transistor T121 and a tenth sub-transistor T122. The gate electrodes of the nineth sub-transistor T121 and the tenth sub-transistor T122 may be connected to the k^{th} PWM light emitting line PWELk, the first electrodes may be connected to the second power supply line VDL2, and the second electrodes may be connected to the first electrode of the eighth transistor T8.

The thirteenth transistor T13 is turned-on by the k^{th} scan control signal of the k^{th} scan control line GCLk and connects the first power supply line VDL1 to a second node N2. The gate electrode of the thirteenth transistor T13 may be connected to the k^{th} scan control line GCLk, the first electrode may be connected to the first power supply line VDL1, and the second electrode may be connected to the second node N2.

The fourteenth transistor T14 is turned-on by the k^{th} PWM light emitting signal of the k^{th} PWM light emitting line PWELk and connects the second power supply line VDL2 to the second node N2. Accordingly, when the fourteenth transistor T14 is turned-on, the second power supply voltage VDD2 of the second power supply line VDL2 may be supplied to the second node N2. The gate electrode of the fourteenth transistor T14 may be connected to the k^{th} PWM light emitting line PWELk, the first electrode may be connected to the second power supply line VDL2, and the second electrode may be connected to the second node N2.

The second capacitor C2 may be disposed between the gate electrode of the eighth transistor T8 and the second node N2. One electrode of the second capacitor C2 may be connected to the gate electrode of the eighth transistor T8, and the other electrode thereof may be connected to the second node N2.

The second node N2 may be the contact point of the second electrode of the thirteenth transistor T13, the second electrode of the fourteenth transistor T14, and the other electrode of the second capacitor C2.

The third pixel driving unit PDU3 adjusts the period in which the driving current is applied to the light emitting element EL according to the voltage of the third node N3.

The third pixel driving unit PDU3 may include fifteenth to nineteenth transistors T15 to T19 and a third capacitor C3.

The fifteenth transistor T15 is turned-on or turned-off depending on the voltage of the third node N3. When the fifteenth transistor T15 is turned-on, the driving current of the eighth transistor T8 may be supplied to the light emitting element EL. Also, when the fifteenth transistor T15 is turned-off, the driving current of the eighth transistor T8 may not be supplied to the light emitting element EL. Therefore, the turned-on period of the fifteenth transistor T15 may be substantially the same as the emission period of the light emitting element EL. The gate electrode of the fifteenth transistor T15 may be connected to the third node N3, the first electrode may be connected to the second electrode of the eighth transistor T8, and the second electrode may be connected to the first electrode of the seventeenth transistor T17.

The sixteenth transistor T16 is turned-on by the k^{th} scan control signal of the k^{th} scan control line GCLk to connect the initialization voltage line VIL to the third node N3. Accordingly, the third node N3 may be discharged to the initialization voltage of the initialization voltage line VIL during the turned-on period of the sixteenth transistor T16.

The sixteenth transistor T16 may include the plurality of transistors connected in series. For example, the sixteenth transistor T16 may include an eleventh sub-transistor T161 and a twelfth sub-transistor T162. Accordingly, it is possible to prevent the voltage of the third node N3 from leaking through the sixteenth transistor T16. The gate electrode of the eleventh sub-transistor T161 may be connected to the k^{th} scan control line GCLk, the first electrode may be connected to the third node N3, and the second electrode may be connected to the first electrode of the twelfth sub-transistor T162. The gate electrode of the twelfth sub-transistor T162 may be connected to the k^{th} scan control line GCLk, the first electrode may be connected to the second electrode of the eleventh sub-transistor T161, and the second electrode may be connected to the initialization voltage line VIL.

The seventeenth transistor T17 is turned-on by a k^{th} PAM emission signal of the k^{th} PAM light emitting line PAELk to connect the second electrode of the fifteenth transistor T15 to the first electrode of the light emitting element EL. The gate electrode of the seventeenth transistor T17 may be connected to the k^{th} PAM light emitting line PAELk, the first electrode may be connected to the second electrode of the fifteenth transistor T15, and the second electrode may be connected to the first electrode of the light emitting element EL.

The eighteenth transistor T18 is turned-on by the k^{th} scan control signal of the k^{th} scan control line GCLk to connect the initialization voltage line VIL to the first electrode of the light emitting element EL. Accordingly, the first electrode of the light emitting element EL may be discharged to the initialization voltage of the initialization voltage line VIL during the turned-on period of the eighteenth transistor T18. The gate electrode of the eighteenth transistor T18 may be connected to the k^{th} scan control line GCLk, the first electrode may be connected to the first electrode of the light emitting element EL, and the second electrode may be connected to the initialization voltage line VIL.

The nineteenth transistor T19 is turned-on by a test signal of a test signal line TSTL to connect the first electrode of the light emitting element EL to the third power supply line VSL. The gate electrode of the nineteenth transistor T19 may be connected to the test signal line TSTL, the first electrode may be connected to the first electrode of the light emitting element EL, and the second electrode may be connected to the third power supply line VSL. The nineteenth transistor T19 may include a plurality of transistors T191 and T192 connected in series. The gate electrodes of the sub-transistors T191 and T192 may be connected to the test signal line TSTL. The first electrode of T191 may be connected the first electrode of the light emitting element EL and the second electrode of T191 may be connected to the first electrode of T192. The first electrode of T192 may be connected the second electrode of T191 and the second electrode of T192 may be connected to the third power supply line VSL.

The third capacitor C3 may be disposed between the third node N3 and the initialization voltage line VIL. One electrode of the third capacitor C3 may be connected to the third node N3, and the other electrode thereof may be connected to the initialization voltage line VIL.

The third node N3 may be the contact point of the second electrode of the sixth transistor T6, the gate electrode of the fifteenth transistor T15, the first electrode of the eleventh sub-transistor T161, and one electrode of the third capacitor C3.

One of the first electrode and the second electrode of each of the first to nineteenth transistors T1 to T19 may be a source electrode, and the other may be a drain electrode. The active layer of each of the first to nineteenth transistors T1 to T19 may be formed of one of poly silicon, amorphous silicon, and/or an oxide semiconductor. When the active layer of each of the first to nineteenth transistors T1 to T19 is polysilicon, it may be formed through a low temperature polysilicon (LTPS) process.

In addition, in FIG. 5, it has been mainly described that each of the first to nineteenth transistors T1 to T19 is formed of a P-type MOSFET, but the present disclosure is not limited thereto. For example, each of the first to nineteenth transistors T1 to T19 may be formed of an N-type MOSFET.

Alternatively, the first sub-transistor T31 and the second sub-transistor T32 of the third transistor T3, the third sub-transistor T41 and the fourth sub-transistor T42 of the fourth transistor T4, the fifth sub-transistor T101 and the sixth sub-transistor T102 of the tenth transistor T10, the seventh sub-transistor T111 and the eighth sub-transistor T112 of the eleventh transistor T11 in the first sub-pixel SP1 may be formed of the N-type MOSFET to increase the ability of the light emitting element EL to express black by blocking leakage current. In this case, the gate electrode of the third sub-transistor T41 and the gate electrode of the fourth sub-transistor T42 of the fourth transistor T4 and the gate electrode of the seventh sub-transistor T111 and the gate electrode of the eighth sub-transistor T112 of the eleventh transistor T11 may be connected to the k^{th} control signal. The k^{th} scan initialization signal GILk and the k^{th} control signal may have pulses generated as gate-off voltages VGH. In addition, the first sub-transistor T31 and the second sub-transistor T32 of the third transistor T3, the third sub-transistor T41 and the fourth sub-transistor T42 of the fourth transistor T4, the fifth sub-transistor T101 and the sixth sub-transistor T102 of the tenth transistor T10, and the active layers of the seventh sub-transistor T111 and the eighth sub-transistor T112 of the eleventh transistor T11 are formed of the oxide semiconductor and the remaining transistors may be formed of polysilicon.

Alternatively, one of the first sub-transistor T31 and the second sub-transistor T32 of the third transistor T3 may be formed of the N-type MOSFET, and the other may be formed of the P-type MOSFET. In this case, a transistor formed of the N-type MOSFET among the first sub-transistor T31 and the second sub-transistor T32 of the third transistor T3 may be formed of the oxide semiconductor, a transistor formed of an N-type MOSFET is formed of the oxide semiconductor, and a transistor formed from the P-type MOSFET may be formed from polysilicon.

Alternatively, one of the third sub-transistor T41 and the fourth sub-transistor T42 of the fourth transistor T4 may be formed of the N-type MOSFET, and the other may be formed of the P-type MOSFET. In this case, a transistor formed of an N-type MOSFET from among the third sub-transistor T41 and the fourth sub-transistor T42 of the fourth transistor T4 may be formed of the oxide semiconductor, and a transistor formed of the P-type MOSFET may be formed of polysilicon.

Alternatively, one of the fifth sub-transistor T101 and the sixth sub-transistor T102 of the tenth transistor T10 may be formed of the N-type MOSFET, and the other one may be formed of the P-type MOSFET. In this case, a transistor formed of the N-type MOSFET from among the fifth sub-transistor T101 and the sixth sub-transistor T102 of the tenth transistor T10 may be formed of the oxide semiconductor, and a transistor formed of the P-type MOSFET may be formed of polysilicon.

Alternatively, one of the seventh sub-transistor T111 and the eighth sub-transistor T112 of the eleventh transistor T11 may be formed of the N-type MOSFET, and the other may be formed of the P-type MOSFET. In this case, a transistor formed of the N-type MOSFET from among the seventh sub-transistor T111 and the eighth sub-transistor T112 of the eleventh transistor T11 may be formed of the oxide semiconductor, and a transistor formed of the P-type MOSFET may be formed of polysilicon.

In one or more embodiments, the second sub-pixel SP2 and the third sub-pixel SP3 according to one or more embodiments may be substantially the same as the first sub-pixel SP1 described in connection with FIG. 5. Therefore, descriptions of the second sub-pixel SP2 and the third sub-pixel SP3 according to one or more embodiments may not be repeated.

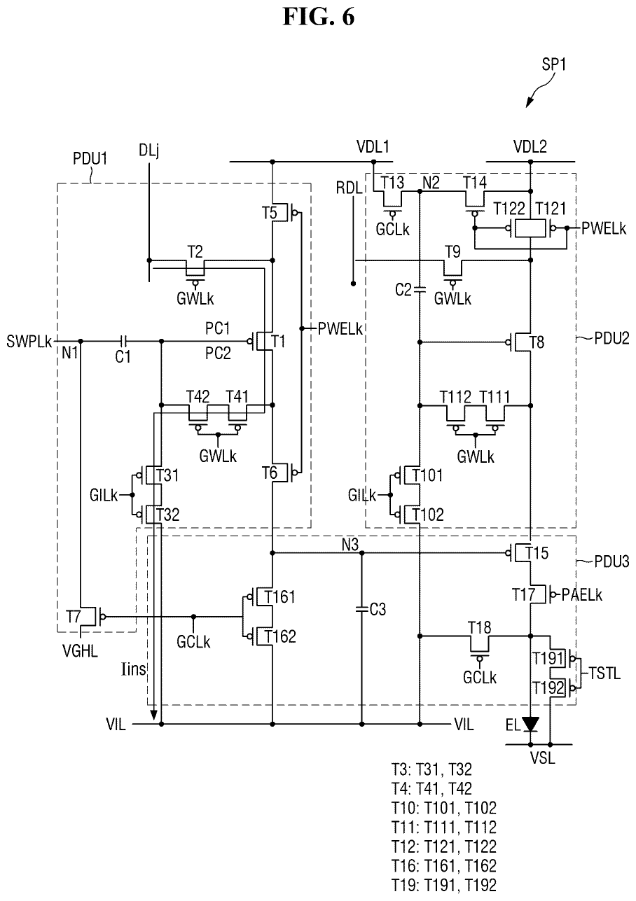

FIG. 6 is an equivalent circuit view illustrating a current path flowing through a first sub-pixel in an inspection process according to one or more embodiments.

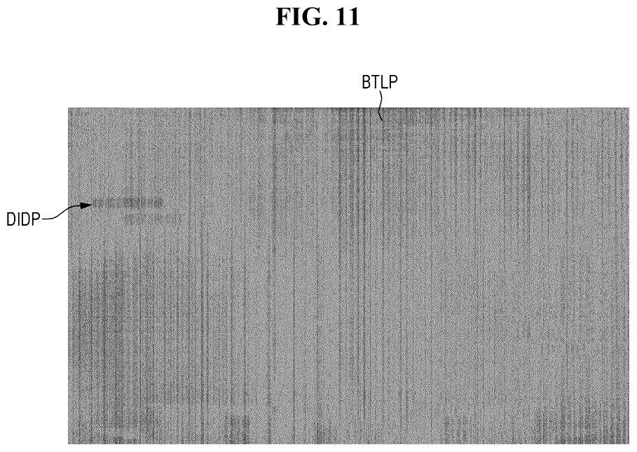

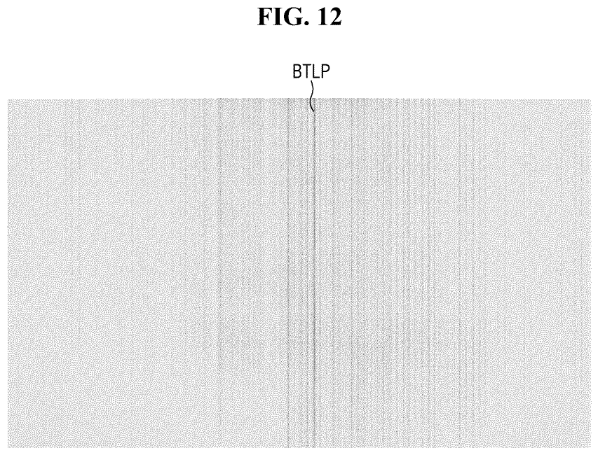

Referring to FIG. 6, the first transistor T1, the second transistor T2, the third transistor T3, the fourth transistor T4, and the seventh transistor T7 may be turned-on, and the fifth transistor T5 and the fifth transistor T5 and the sixth transistor T6 of the first pixel driving unit PDU1 may be turned-off in the inspection process. Due to the turn-on of the first transistor T1, the second transistor T2, the third transistor T3, and the fourth transistor T4 in the inspection mode, a current may flow from the first pixel driving unit PDU1 to the initialization voltage line VIL through the second transistor T2, the first transistor T1, the fourth transistor T4, and the third transistor T3 from the j^{th} data line DLj. Therefore, current values of the sub-pixels SP1, SP2, and SP3 of all pixels PX may be calculated by sensing the current through the data line DLj. Accordingly, as shown in FIGS. 11 and 12, a current value image showing current values may be calculated by mapping the current values to the sub-pixels SP1, SP2, and SP3 of the pixels PX, respectively.

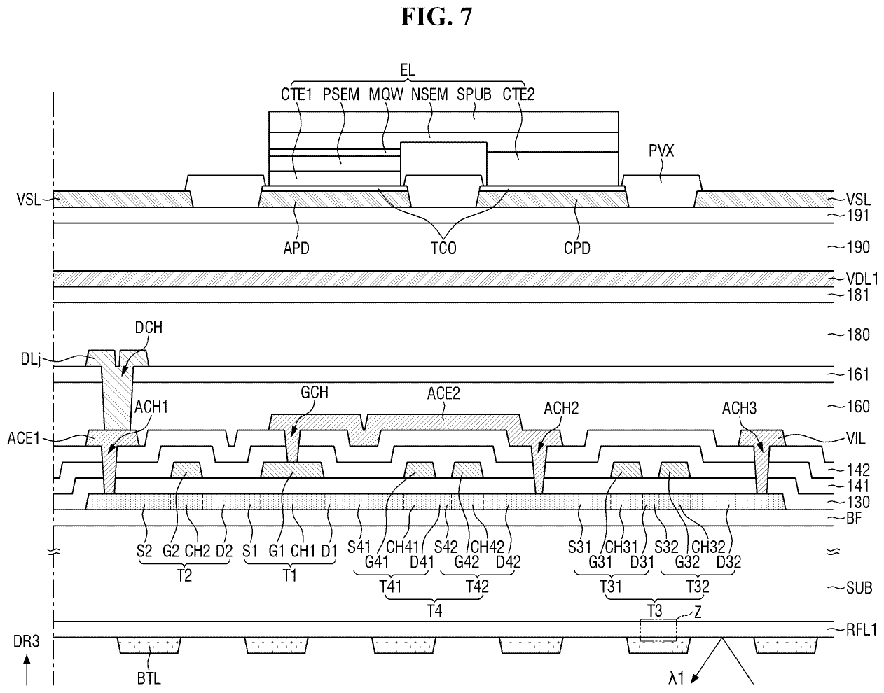

FIG. 7 is a cross-sectional view illustrating one example of the first to fourth transistors and light emitting elements of the first sub-pixel according to one or more embodiments.

Referring to FIG. 7, the substrate SUB may be made of an insulating material such as glass and/or polymer resin. For example, when the substrate SUB is made of a polymer resin, it may include polyimide. The substrate SUB may be a flexible substrate capable of bending, folding, rolling, and/or the like.

A buffer layer BF may be disposed on the first surface of the substrate SUB. The buffer layer BF may be formed of a plurality of inorganic layers alternately stacked. For example, the buffer layer BF may be formed as a multilayer in which one or more inorganic layers of a silicon nitride layer, a silicon oxynitride layer, a silicon oxide layer, a titanium oxide layer, and an aluminum oxide layer are alternately stacked.

An active layer may be disposed on the buffer film BF. The active layer includes the first to nineteenth channels, the first to nineteenth source electrodes, and the first to nineteenth drain electrodes of the first to nineteenth transistors T1 to T19 shown in FIG. 5. The active layer may include polycrystalline silicon, single crystal silicon, low temperature polycrystalline silicon, amorphous silicon, and/or an oxide semiconductor. The first to nineteenth source electrodes and the first to nineteenth drain electrodes may be regions having conductivity by doping a silicon semiconductor and/or an oxide semiconductor with ions or impurities.

In FIG. 7, as the active layer, a first channel CH1, a first source electrode S1, and a first drain electrode D1 of the first transistor T1, a second channel CH2, a second source electrode S2, and a second drain electrode D2 of the second transistor T2, a first sub-channel CH31 of the first sub-transistor T31 of the third transistor T3, a first sub-source electrode S31, and a first sub-drain electrode D31, a second sub-channel CH32 of the second sub-transistor T32 of the third transistor T3, a second sub-source electrode S32, and a second sub-drain electrode D32, a third sub-channel CH41 of the third sub-transistor T41 of the fourth transistor T4, a third sub-source electrode S41, and a third sub-drain electrode D41, the fourth sub-channel CH42 of the fourth sub-transistor T42 of the fourth transistor T4, the fourth sub-source electrode S42, and a fourth sub-drain electrode D42 are shown.

A gate insulating film 130 may be disposed on the active layer. The gate insulating film 130 may be formed of an inorganic layer, for example, a silicon nitride layer, a silicon oxynitride layer, a silicon oxide layer, a titanium oxide layer, and/or an aluminum oxide layer.

A first gate metal layer may be disposed on the gate insulating film 130. The first gate metal layer includes the first to nineteenth gate electrodes and the first to third gate connection electrodes of the first to nineteenth transistors T1 to T19 shown in FIG. 5. The first gate metal layer may be formed as a single layer or multiple layers made of at least one of molybdenum (Mo), aluminum (Al), chromium (Cr), gold (Au), titanium (Ti), nickel (Ni), neodymium (Nd), and/or copper (Cu) and/or an alloy thereof.

In FIG. 7, a first gate electrode G1 of the first transistor T1, a second gate electrode G2 of the second transistor T2, a first sub-gate electrode G31 of the first sub-transistor T31 of the third transistor T3, and a second sub-gate electrode G32 of the second sub-transistor T32 of the third transistor T3, a third sub-gate electrode G41 of the third sub-transistor T41 of the fourth transistor T4, and a fourth sub-gate electrode G42 of the fourth sub-transistor T42 of the fourth transistor T4 are shown as the first gate metal layer.

The first channel CH1 of the first transistor T1 overlaps the first gate electrode G1 in a third direction DR3 (e.g., a thickness direction of the substrate SUB) but does not overlap the first source electrode S1 and the first drain electrode D1. The second channel CH2 of the second transistor T2 overlaps the second gate electrode G2 in the third direction DR3 but does not overlap the second source electrode S2 and the second drain electrode D2. The first sub-channel CH31 of the first sub-transistor T31 overlaps the first sub-gate electrode G31 in the third direction DR3 but does not overlap the first sub-source electrode S31 and the first sub-drain electrode D31. The second sub-channel CH32 of the second sub-transistor T32 overlaps the second sub-gate electrode G32 in the third direction DR3 but does not overlap the third sub-source electrode S32 and the second sub-drain electrode D32. The third sub-channel CH41 of the third sub-transistor T41 overlaps the third sub-gate electrode G41 in the third direction DR3 but does not overlap the third sub-source electrode S41 and the third sub-drain electrode D41. The fourth sub-channel CH42 of the fourth sub-transistor T42 overlaps the fourth sub-gate electrode G42 in the third direction DR3 but does not overlap the fourth sub-source electrode S42 and the fourth sub-drain electrode D42.

A first interlayer insulating layer 141 may be disposed on the first gate metal layer. The first interlayer insulating layer 141 may be formed of an inorganic layer, such as a silicon nitride layer, a silicon oxy nitride layer, a silicon oxide layer, a titanium oxide layer, and/or an aluminum oxide layer.

A second gate metal layer may be disposed on the first interlayer insulating layer 141. The second gate metal layer includes one electrode of the first capacitor C1, one electrode of the second capacitor C2, and one electrode of the third capacitor C3 shown in FIG. 5. The second gate metal layer may be formed as a single layer or multiple layers of at least one of molybdenum (Mo), aluminum (Al), chromium (Cr), gold (Au), titanium (Ti), nickel (Ni), neodymium (Nd), and/or copper (Cu), and/or an alloy thereof.

A second interlayer insulating film 142 may be disposed on the second gate metal layer. The second interlayer insulating film 142 may be formed of an inorganic film, such as a silicon nitride layer, a silicon oxynitride layer, a silicon oxide layer, a titanium oxide layer, and/or an aluminum oxide layer.

A first source metal layer may be disposed on the second interlayer insulating film 142. The first source metal layer includes a first source connection electrode ACE1, a second source connection electrode ACE2, and an initialization power supply line VIL. The first source metal layer may be formed as a single layer or multiple layers of at least one of molybdenum (Mo), aluminum (Al), chromium (Cr), gold (Au), titanium (Ti), nickel (Ni), neodymium (Nd), and/or copper (Cu), and/or an alloy thereof.

The first source connection electrode ACE1 may be connected to the second source electrode S2 of the second transistor T2 through a first active contact hole ACH1 penetrating the gate insulating film 130, a first interlayer insulating film 141, and a second interlayer insulating film 142. The second source connection electrode ACE2 may be connected to a first gate electrode G1 of the first transistor T1 through a gate contact hole GCH penetrating the first interlayer insulating film 141 and the second interlayer insulating film 142. In addition, the second source connection electrode ACE2 may be connected to the first sub-source electrode S31 of the first sub-transistor T31 and the fourth sub-drain electrode D42 of the fourth sub-transistor T42 through a second active contact hole ACH2 penetrating the gate insulating film 130, the first interlayer insulating film 141, and the second interlayer insulating film 142. The initialization power supply line VIL may be connected to the second sub-drain electrode D32 of the second sub-transistor T32 through a third active contact hole ACH3 penetrating the gate insulating film 130, the first interlayer insulating film 141, and the second interlayer insulating film 142.

A first planarization film 160 may be disposed on the first source metal layer. The first planarization film 160 may be formed from an organic film such as an acrylic resin, an epoxy resin, a phenolic resin, a polyamide resin, a polyimide resin, and/or the like.

A first inorganic insulating film 161 may be disposed on the first planarization film 160. The first inorganic insulating film 161 may be formed of an inorganic film, such as a silicon nitride layer, a silicon oxynitride layer, a silicon oxide layer, a titanium oxide layer, and/or an aluminum oxide layer.

A second source metal layer may be disposed on the first inorganic insulating film 161. The second source metal layer includes a j^{th} data line DLj. The second source metal layer may be formed as a single layer or multiple layers of at least one of molybdenum (Mo), aluminum (Al), chromium (Cr), gold (Au), titanium (Ti), nickel (Ni), neodymium (Nd), and/or copper (Cu), and/or an alloy thereof.

A second planarization film 180 may be disposed on the second source metal layer. The second planarization film 180 may be formed of an organic film, such as an acrylic resin, an epoxy resin, a phenolic resin, a polyamide resin, a polyimide resin, and/or the like.

A second inorganic insulating film 181 may be disposed on the second planarization film 180. The second inorganic insulating film 181 may be formed of an inorganic film, such as a silicon nitride layer, a silicon oxynitride layer, a silicon oxide layer, a titanium oxide layer, and/or an aluminum oxide layer.

A third source metal layer may be disposed on the second inorganic insulating film 181. The third source metal layer DTL3 includes the first power supply line VDL1 shown in FIG. 5. The third source metal layer DTL3 may be formed as a single layer or multiple layers of at least one of molybdenum (Mo), aluminum (Al), chromium (Cr), gold (Au), titanium (Ti), nickel (Ni), neodymium (Nd), and/or copper (Cu), and/or an alloy thereof.

A third planarization film 190 may be disposed on the third source metal layer. The third planarization film 190 may be formed from an organic film such as an acrylic resin, an epoxy resin, a phenolic resin, a polyamide resin, a polyimide resin, and/or the like.

A third inorganic insulating film 191 may be disposed on the third planarization film 190. The third inorganic insulating film 191 may be formed of an inorganic film, such as a silicon nitride layer, a silicon oxynitride layer, a silicon oxide layer, a titanium oxide layer, and/or an aluminum oxide layer.

A fourth source metal layer may be disposed on the third inorganic insulating film 191. The fourth source metal layer includes the third power supply line VSL, an anode pad electrode APD, and a cathode electrode CPD shown in FIG. 5. The fourth source metal layer may be formed as a single layer or multiple layers of at least one of molybdenum (Mo), aluminum (A1), chromium (Cr), gold (Au), titanium (Ti), nickel (Ni), neodymium (Nd), and/or copper (Cu), and/or an alloy thereof.

The third power supply line VSL, the anode pad electrode APD, and the cathode electrode CPD may be disposed apart (e.g., spaced) from each other. That is, the third power supply line VSL, the anode pad electrode APD, and the cathode electrode CPD may be electrically separated.

A transparent metal layer TCO may be disposed on the anode pad electrode APD and the cathode pad electrode CPD. The transparent metal layer TCO may be a layer to increase adhesion with a first contact electrode CTE1 and the second contact electrode CTE2 of the light emitting element EL. The transparent metal layer TCO may be formed from a transparent conductive oxide, such as indium tin oxide (ITO) and/or indium zinc oxide (IZO).

A protective film PVX may be disposed on the third power supply line VSL, the anode pad electrode APD, cathode pad electrode CPD, and transparent metal layer TCO. The protective film PVX may be disposed to cover the edges of the third power supply line VSL, the anode pad electrode APD, the cathode pad electrode CPD, and the transparent metal layer TCO. The protective film PVX may be formed of an inorganic film, such as a silicon nitride layer, a silicon oxynitride layer, a silicon oxide layer, a titanium oxide layer, and/or an aluminum oxide layer.

The light emitting element EL is a flip chip type micro LED in which the first contact electrode CTE1 and the second contact electrode CTE2 are disposed to face the anode pad electrode APD and the cathode pad electrode CPD. The light emitting element EL may be an inorganic light emitting element made of an inorganic material such as gallium nitride (GaN). The light emitting element EL may have a length of several to hundreds of μm in the first direction DR1, the second direction DR2, and the third direction DR3. For example, each of the lengths of the light emitting element EL in the first direction DR1, in the second direction DR2, and in the third direction DR3 may be about 100 μm or less.

The light emitting elements EL may be formed by being grown on a semiconductor substrate such as a silicon wafer. Each of the light emitting elements EL may be transferred directly from the silicon wafer onto the anode pad electrode APD and the cathode pad electrode CPD of the substrate SUB. Alternatively, each of the light emitting elements EL may be transferred to the anode pad electrode APD and the cathode pad electrode CPD of the substrate SUB through an electrostatic method using an electrostatic head or a stamp method using an elastic polymer material such as PDMS or silicon as a transfer substrate.

Each of the light emitting elements EL may be a light emitting structure including a base substrate SPUB, an n-type semiconductor NSEM, an active layer MQW, a p-type semiconductor PSEM, a first contact electrode CTE1, and a second contact electrode CTE2.

The base substrate SPUB may be a sapphire substrate, but the present disclosure is not limited thereto.

The n-type semiconductor NSEM may be disposed on one surface of the base substrate SPUB. For example, the n-type semiconductor NSEM may be disposed on the lower surface of the base substrate SPUB. The n-type semiconductor NSEM may be made of GaN doped with an n-type conductivity-type dopant such as Si, Ge, and/or Sn.

The active layer MQW may be disposed on a portion of one surface of the n-type semiconductor NSEM. The active layer MQW may include a material having a single or multiple quantum well structure. When the active layer contains a material having a multiple quantum well structure, the active layer may have the structure in which a plurality of well layers and barrier layers are alternately laminated. In this case, the well layer may be formed of InGaN, and the barrier layer may be formed of GaN or AlGaN but is not limited thereto. Alternatively, the active layer may have a structure in which semiconductor materials having large band gap energy and semiconductor materials having small band gap energy are alternately stacked and may include other Group Ill to Group V semiconductor materials according to a wavelength band of the emitted light.

The p-type semiconductor PSEM may be disposed on one surface of the active layer MQW. The p-type semiconductor PSEM may be made of GaN doped with a p-type conductivity-type dopant such as Mg, Zn, Ca, Se, and/or Ba.

The first contact electrode CTE1 may be disposed on the p-type semiconductor PSEM, and the second contact electrode CTE2 may be disposed on another portion of one surface of the n-type semiconductor NSEM. Another portion of one surface of the n-type semiconductor NSEM on which the second contact electrode CTE2 is disposed may be disposed apart (e.g., spaced) from a portion of one surface of the n-type semiconductor NSEM on which the active layer MQW is disposed.

The first contact electrode CTE1 and the anode pad electrode APD may be adhered to each other through the conductive adhesive such as an anisotropic conductive film ACF or an anisotropic conductive paste ACP. Alternatively, the first contact electrode CTE1 and the anode pad electrode APD may be bonded to each other through a soldering process.

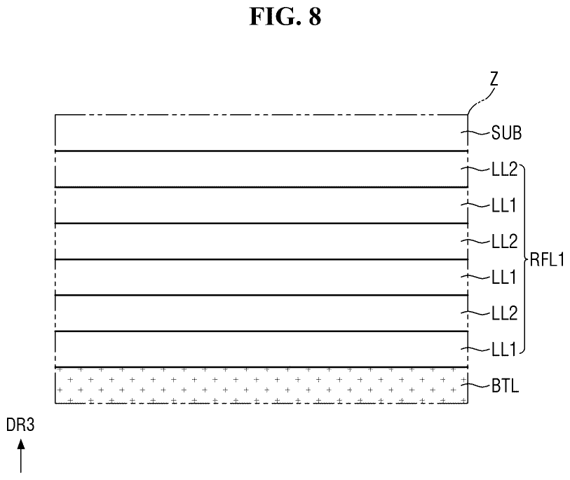

A first selective reflective film RFL1 may be disposed on a second surface of the substrate SUB opposite to the first surface. The first surface of the substrate SUB may be the front surface of the substrate SUB, and the second surface of the substrate SUB may be the rear surface of the substrate SUB. The first selective reflective film RFL1 may be designed to mainly reflect the light A1 of a first wavelength incident on the second surface of the substrate SUB. The light A1 of the first wavelength may be light having a wavelength of 310 nm or less. A detailed description of the first selective reflective film RFL1 will be described later in conjunction with FIGS. 8 to 12.

A fifth source metal layer may be disposed on the first selective reflective film RFL1. The fifth source metal layer includes bottom wirings BTL. The bottom wirings BTL may include the first bottom fan-out wirings BFL1 and the second bottom fan-out wirings BFL2 shown in FIG. 2. The fifth source metal layer may be formed as a single layer or multiple layers of at least one of molybdenum (Mo), aluminum (Al), chromium (Cr), gold (Au), titanium (Ti), nickel (Ni), neodymium (Nd), and/or copper (Cu), and/or an alloy thereof.

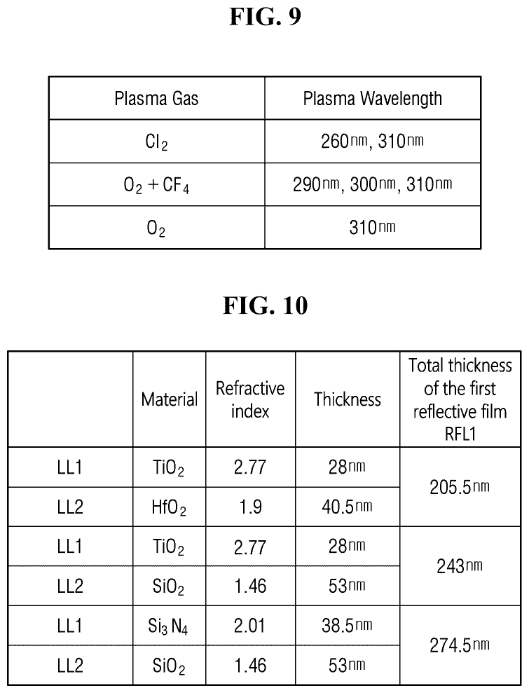

FIG. 8 is an enlarged cross-sectional view illustrating one example of the first selective reflective film of FIG. 7 in detail. FIG. 9 is a table showing plasma wavelengths generated by different plasma gas used to pattern the bottom wiring shown in FIG. 2. FIG. 10 is a table showing the first reflective metal layer and the second reflective metal layer and the thickness of the first reflective metal layer and the thickness of the second reflective metal layer calculated according to a first target wavelength shown in FIG. 8.

As shown in FIG. 8, the first selective reflective film RFL1 may serve as a distributed Bragg reflector. That is, the first selective reflective film RFL1 may reflect light of a first wavelength and transmit light of other wavelengths. The first wavelength may be a target reflection wavelength that the first selective reflective film RFL1 intends to reflect.

The first selective reflective film RFL1 includes M (M is an integer greater than or equal to 2) pairs of a first layer LL1 and a second layer LL2 to serve as the distributed Bragg reflector. The M first layers LL1 and M second layers LL2 may be alternately disposed. In each of the M pairs, the second layer LL2 may be disposed closer to the substrate SUB than the first layer LL1. For example, the three pairs of first and second layers LL1 and LL2 of the first selective reflective film RFL1 may be disposed in the order of the bottom wiring BTL, the first layer LL1, the second layer LL2, the first layer LL1, the second layer LL2, the first layer LL1, the second layer LL2, and the substrate SUB in the third direction DR3.

As shown in FIG. 9, in the process of forming the bottom wiring BTL chlorine (Cl₂) gas, oxygen (O₂) gas, carbon tetrafluoride (CF₄), and oxygen (O₂) gas may be used as materials for etching the bottom wiring BTL. For example, chlorine (Cl₂) gas may be a material directly involved in the etching of bottom wiring BTL, and oxygen (O₂) gas, carbon tetrafluoride (CF₄), and oxygen (O₂) gas may be post-treatment materials used for process optimization.

At this time, from among the light emitted from the chlorine (Cl₂) gas, the wavelengths of short-wavelength light having high energy may be 260 nm and 310 nm. Also, the wavelengths of the high-energy short-wavelength light emitted by the oxygen (O₂) gas and the carbon tetrafluoride (CF₄) gas may be 290 nm, 300 nm, and 310 nm. Further, the wavelength of the high-energy, short-wavelength light emitted by oxygen (O₂) gas may be 310 nm.

When high-energy short-wavelength light is incident on the channels of the first to nineteenth transistors T1-T19, the characteristics of the first to nineteenth transistors T1-T19 may be changed by being affected by the short-wavelength light. For example, the threshold voltages of the first to nineteenth transistors T1 to T19 may be positively shifted.

However, from among the first to nineteenth channels of the first to nineteenth transistors T1 to T19, the short-wavelength light may not be incident to channels overlapping the bottom wirings BTL in the third direction DR3. Therefore, a characteristic difference may occur between a transistor that is positively shifted by being affected by the short-wavelength light and a transistor that is not positively shifted by not being affected by the short-wavelength light.

The target reflection wavelength to be reflected by the first selective reflective film RFL1 may be 310 nm or less. For example, the target reflection wavelength of the first selective reflective film RFL1 may be 310 nm emitted from all of chlorine (Cl₂) gas, oxygen (O₂) gas, carbon tetrafluorocarbon (CF₄), and oxygen (O₂) gas. Alternatively, the target reflection wavelength of the first selective reflective film RFL1 may be 290 nm or 300 nm emitted from oxygen (O₂) gas and carbon tetrafluoride (CF₄). Alternatively, the target reflection wavelength of the first selective reflective film RFL1 may be 260 nm emitted from chlorine (Cl₂) gas.

As shown in FIG. 10, the refractive index of the first layer LL1 may be greater than that of the second layer LL2. The first layer LL1 may be Si₃N₄ or TiO₂, and the second layer LL2 may be SiO₂ or HfO₂. For example, the first layer LL1 may be TiO₂ and the second layer LL2 may be SiO₂ or HfO₂. Alternatively, the first layer LL1 may be Si₃N₄ and the second layer LL2 may be SiO₂.

When the first layer LL1 is TiO₂, the refractive index of the first layer LL1 may be 2.77. Alternatively, when the first layer LL1 is Si₃N₄, the refractive index of the first layer LL1 may be 2.01.

When the second layer LL2 is HfO₂, the refractive index of the second layer LL2 may be 1.9. Alternatively, when the second layer LL2 is SiO₂, the refractive index of the second layer LL2 may be 1.46.

The thickness of the first layer LL1 and the thickness of the second layer LL2 may be calculated as in Equation 1.

$$t = \frac{λ}{4 n} \qquad Equation 1$$

In Equation 1, t indicates the thickness of the first layer LL1 or the second layer LL2 of the first selective reflective film RFL1, A indicates the target reflection wavelength of the first selective reflective film RFL1, and n indicates the refractive index of the first or second layer.

When the first layer LL1 is TiO₂ and the second layer LL2 is HfO₂, a difference between a refractive index of the first layer LL1 and a refractive index of the second layer LL2 may be approximately 0.87. When the target reflection wavelength of the first selective reflective film RFL1 is 310 nm, the thickness of the first layer LL1 may be approximately 28 nm, and the thickness of the second layer LL2 may be approximately 40.5 nm. In this case, when the first selective reflective film RFL1 includes three pairs of first and second layers LL1 and LL2, the total thickness of the first selective reflective film RFL1 may be approximately 205.5 nm.

Alternatively, when the first layer LL1 is TiO₂ and the second layer LL2 is SiO₂, a difference between the refractive index of the first layer LL1 and the refractive index of the second layer LL2 may be approximately 1.31. When the target reflection wavelength of the first selective reflective film RFL1 is 310 nm, the thickness of the first layer LL1 may be approximately 28 nm, and the thickness of the second layer LL2 may be approximately 53 nm. In this case, when the first selective reflective film RFL1 includes three pairs of first and second layers LL1 and LL2, the total thickness of the first selective reflective film RFL1 may be approximately 243 nm.

Alternatively, when the first layer LL1 is Si₃N₄ and the second layer LL2 is SiO₂, a difference between the refractive index of the first layer LL1 and the refractive index of the second layer LL2 may be approximately 0.55. When the target reflection wavelength of the first selective reflective film RFL1 is 310 nm, the thickness of the first layer LL1 may be approximately 38.5 nm, and the thickness of the second layer LL2 may be approximately 53 nm. In this case, when the first selective reflective film RFL1 includes three pairs of first and second layers LL1 and LL2, the total thickness of the first selective reflective film RFL1 may be approximately 274.5 nm.

FIGS. 11 and 12 are current value images showing current values calculated by the inspection process in the presence and absence of the first selective reflective film.

When the display panel 100 does not include the first selective reflective film RFL1, the short-wavelength light of 310 nm or less may be incident to the first to nineteenth channels of the first to nineteenth transistors T1 to T19 of each of the sub-pixels SP1, SP2, and SP3 in a manufacturing process of forming the bottom wirings BTL. In this case, the characteristics of the first to nineteenth transistors T1 to T19 may be changed by being affected by the short-wavelength light. For example, the threshold voltages of the first to nineteenth transistors T1 to T19 may be positively shifted. However, from among the first to nineteenth channels of the first to nineteenth transistors T1 to T19, the short-wavelength light may not be incident to the channels overlapping the bottom wirings BTL in the third direction DR3.

That is, when the display panel 100 does not include the first selective reflective film RFL1, a characteristic difference may occur between the transistor that is positively shifted by being affected by the short-wavelength light and the transistor that is not positively shifted by not being affected by the short-wavelength light. Because whether or not it is affected by short-wavelength light is determined by whether the transistor overlaps the bottom wirings BTL, the bottom wiring patterns BTLP corresponding to the bottom wirings BTL, and the device identifier patterns DIDP corresponding to the device identifiers DID may be recognized in the current value image calculated by the inspection process of FIG. 6 as shown in FIG. 11.

As shown in FIGS. 8 to 10, when the display panel 100 includes the first selective reflective film RFL1 that reflects short-wavelength light of 310 nm or less, the short-wavelength light may be prevented or reduced from being incident on the first to nineteenth channels of the first to nineteenth transistors T1 to T19 of each of the sub-pixels SP1, SP2, and SP3. Accordingly, it is possible to prevent or reduce the positive shift of the threshold voltages of the first to nineteenth transistors T1 to T19 by the short-wavelength light. Therefore, it is possible to reduce or minimize a difference in characteristics between the positive shifted transistor affected by the short-wavelength light and the positive-shifted transistor unaffected by the short-wavelength light. As shown in FIG. 12, the visibility of the bottom wiring patterns BTLP and the device identifier patterns DIDP in the current value image calculated by the inspection process of FIG. 6 may be reduced.

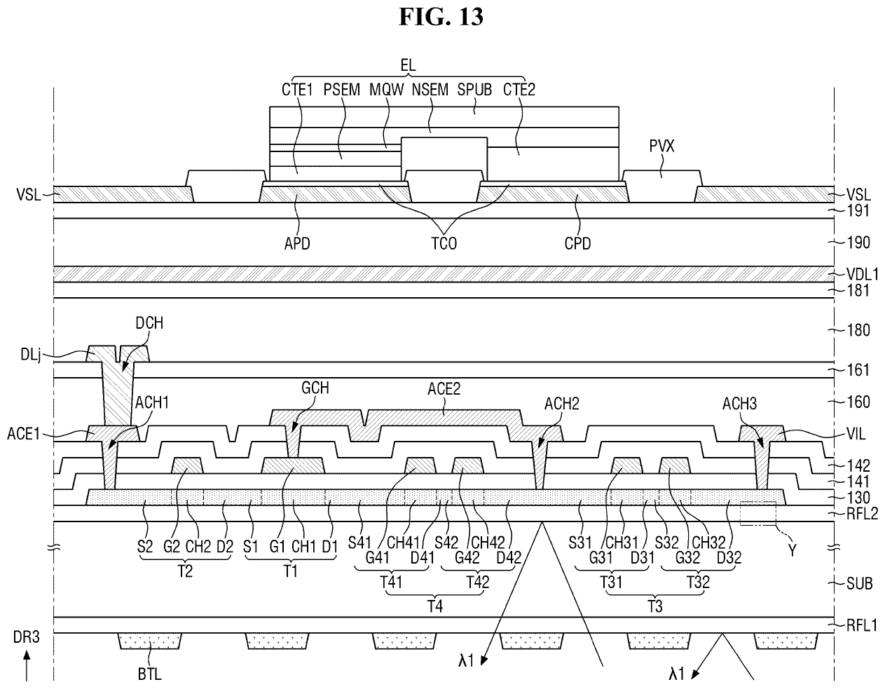

FIG. 13 is a cross-sectional view illustrating an example of the first to fourth transistors of the first sub-pixel according to one or more embodiments.

The embodiment of FIG. 13 is different from the embodiment of FIG. 7 in that the second selective reflection film RFL2 is disposed instead of the buffer film BF. In the embodiment of FIG. 13, redundant descriptions with those of the embodiment of FIG. 7 are omitted.

Referring to FIG. 13, the second selective reflective film RFL2 may be disposed on the first surface of the substrate SUB. The first surface of the substrate SUB may be the front surface of the substrate SUB, and the second surface of the substrate SUB may be the rear surface of the substrate SUB.

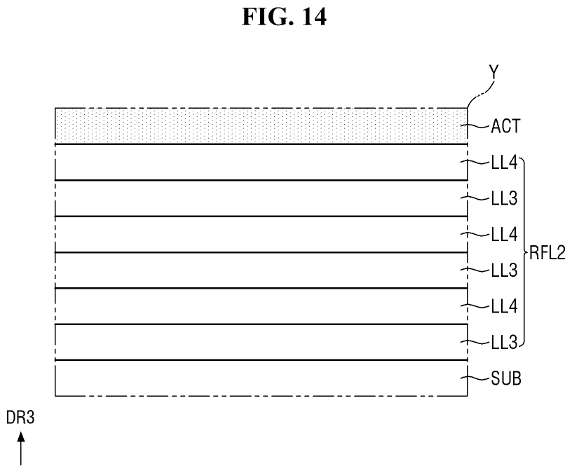

The active layer ACT may be disposed on the second selective reflective film RFL2. The second selective reflective film RFL2 may be designed to mainly reflect light A1 of the first wavelength incident on the second surface of the substrate SUB. A detailed description of the second selective reflective film RFL2 will be described later with reference to FIG. 14.

FIG. 14 is an enlarged cross-sectional view illustrating one example of the second selective reflective film of FIG. 13 in detail.

Referring to FIG. 14, the second selective reflective film RFL2 may serve as the distributed Bragg reflector. That is, the second selective reflective film RFL2 may serve as a selective reflective film that reflects light of a first wavelength and transmits light of another wavelength. To this end, the second selective reflective film RFL2 includes N (N is an integer greater than or equal to 2) pairs of third and fourth layers LL3 and LL4. The N third layers LL3 and N fourth layers LL4 may be alternately disposed. In each of the N pairs, the third layer LL3 may be disposed closer to the substrate SUB than the fourth layer LL3. For example, three pairs of the third layer LL3 and the fourth layer LL4 of the second selective reflective film RFL2 may be disposed in the order of the substrate SUB, the third layer LL3, the fourth layer LL4, the third layer LL3, the fourth layer LL4, the third layer LL3, the fourth layer LL4, and the active layer ACT in the third direction DR3.

The target reflection wavelength to be reflected by the second selective reflective film RFL2 may be substantially the same as the target reflection wavelength of the first selective reflective film RFL1. That is, the target reflection wavelength to be reflected by the second selective reflective film RFL2 may be 310 nm or less. In this case, the material, refractive index, and thickness of the third layer LL3 may be substantially the same as the material, refractive index, and thickness of the first layer LL1. Also, the material, refractive index, and thickness of the fourth layer LL4 may be substantially the same as the material, refractive index, and thickness of the second layer LL2. That is, the material, refractive index, and thickness of the third layer LL3, the material, refractive index, and thickness of the fourth layer LL4, and the thickness of the second selective reflective film RFL2 may be substantially the same as the material, refractive index, and thickness of the first layer LL1, the material, refractive index, and thickness of the second layer LL2, and the thickness of the first selective reflective film RFL1.

As shown in FIGS. 13 and 14, because the second selective reflective film RFL2 has the same target reflection wavelength as the first selective reflective film RFL1, the light A1 of the first wavelength passing through the first selective reflective film RFL1 without being reflected by the first selective reflective film RFL1 may be reflected by the second selective reflective film RFL2. Therefore, the short-wavelength light of 310 nm or less may be further prevented from being incident on the first to nineteenth channels of the first to nineteenth transistors T1 to T19 of each of the sub-pixels SP1, SP2, and SP3.

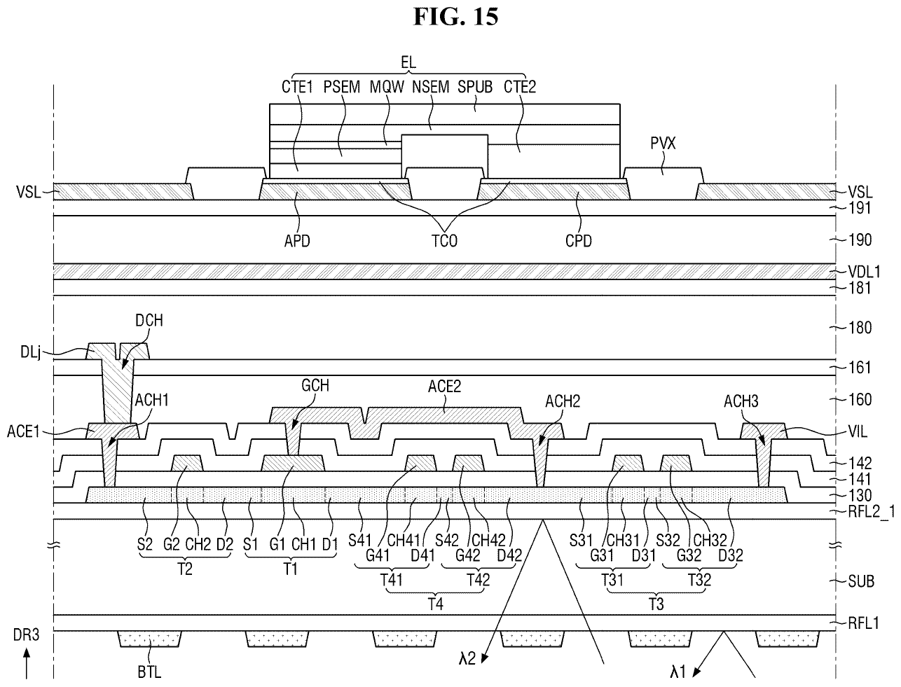

FIG. 15 is a cross-sectional view illustrating one example of the first to fourth transistors of the first sub-pixel according to one or more embodiments.

The embodiment of FIG. 15 is different from the embodiment of FIG. 7 in that a second selective reflection film RFL2_1 is disposed instead of the buffer film BF. In the embodiment of FIG. 15, redundant descriptions with those of the embodiment of FIG. 7 are omitted.

Referring to FIG. 15, the second selective reflective film RFL2_1 may be disposed on the first surface of the substrate SUB. The first surface of the substrate SUB may be the front surface of the substrate SUB, and the second surface of the substrate SUB may be the rear surface of the substrate SUB.

The active layer may be disposed on the second selective reflective film RFL2_1. The second selective reflective film RFL2_1 may be designed to mainly reflect light A2 of the second wavelength incident on the second surface of the substrate SUB. That is, the target reflection wavelength to be reflected by the second selective reflective film RFL2_1 is 310 nm or less, but the target reflection wavelength to be reflected by the second selective reflective film RFL2_1 may be different from the target reflection wavelength of the first selective reflective film RFL1.

For example, when the target reflection wavelength of the first selective reflective film RFL1 is 310 nm emitted from both chlorine (Cl₂) gas, oxygen (O₂) gas and carbon tetrafluoride (CF₄), and oxygen (O₂) gas, the target reflection wavelength of the second selective reflective film RFL2_1 may be 290 nm or 300 nm emitted from oxygen (O₂) gas and carbon tetrafluoride (CF₄). Alternatively, the target reflection wavelength of the second selective reflective film RFL2_1 may be 260 nm emitted from chlorine (Cl₂) gas.

As shown in FIG. 15, because the second selective reflective film RFL2 has the target reflection wavelength different from that of the first selective reflective film RFL1, the light A2 of the second wavelength passing through the first selective reflective film RFL1 without being reflected by the first selective reflective film RFL1 may be reflected by the second selective reflective film RFL2. Therefore, the short-wavelength light of 310 nm or less may be further prevented from being incident on the first to nineteenth channels of the first to nineteenth transistors T1 to T19 of each of the sub-pixels SP1, SP2, and SP3.

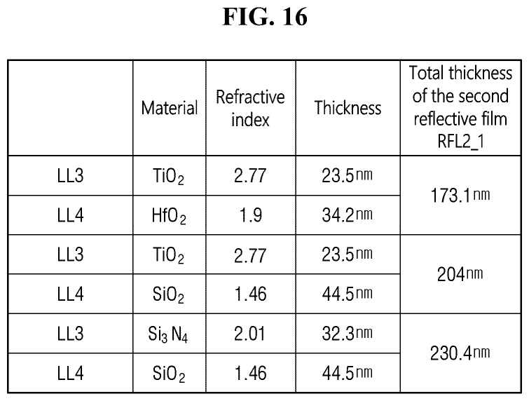

FIG. 16 is a table showing the third reflective metal layer and the fourth reflective metal layer and the thickness of the third reflective metal layer and the thickness of the fourth reflective metal layer calculated according to a second target wavelength shown in FIG. 14.

Referring to FIG. 16, the second selective reflective film RFL2_1 may have substantially the same structure as described in conjunction with FIG. 14.

When the third layer LL3 is TiO₂ and the fourth layer LL4 is HfO₂, the third layer LL3 may have a refractive index of 2.77 and the fourth layer LL4 may have a refractive index of 1.9. A difference between the refractive index of the third layer LL3 and the refractive index of the fourth layer LL4 may be approximately 0.87. When the target reflection wavelength of the second selective reflective film RFL2_1 is 260 nm, the thickness of the third layer LL3 may be approximately 23.5 nm, and the thickness of the fourth layer LL4 may be approximately 34.2 nm. In this case, when the second selective reflective film RFL2_1 includes three pairs of third and fourth layers LL3 and LL4, the total thickness of the second selective reflective film RFL2_1 may be approximately 173.1 nm.

Alternatively, when the third layer LL3 is TiO₂ and the fourth layer LL4 is SiO₂, the refractive index of the third layer LL3 may be 2.77 and the refractive index of the fourth layer LL4 may be 1.46. A difference between the refractive index of the third layer LL3 and the refractive index of the fourth layer LL4 may be approximately 1.31. When the target reflection wavelength of the second selective reflective film RFL2_1 is 260 nm, the thickness of the third layer LL3 may be approximately 23.5 nm, and the thickness of the fourth layer LL4 may be approximately 44.5 nm. In this case, when the second selective reflective film RFL2_1 includes three pairs of third and fourth layers LL3 and LL4, the total thickness of the second selective reflective film RFL2_1 may be approximately 204 nm.

Alternatively, when the third layer LL3 is Si₃N₄ and the fourth layer LL4 is SiO₂, the third layer LL3 may have a refractive index of 2.01 and the fourth layer LL4 may have a refractive index of 1.46. A difference between the refractive index of the third layer LL3 and the refractive index of the fourth layer LL4 may be approximately 0.55. When the target reflection wavelength of the second selective reflective film RFL2_1 is 260 nm, the thickness of the third layer LL3 may be approximately 32.3 nm, and the thickness of the fourth layer LL4 may be approximately 44.5 nm. In this case, when the second selective reflective film RFL2_1 includes three pairs of third and fourth layers LL3 and LL4, the total thickness of the second selective reflective film RFL2_1 may be approximately 230.4 nm.

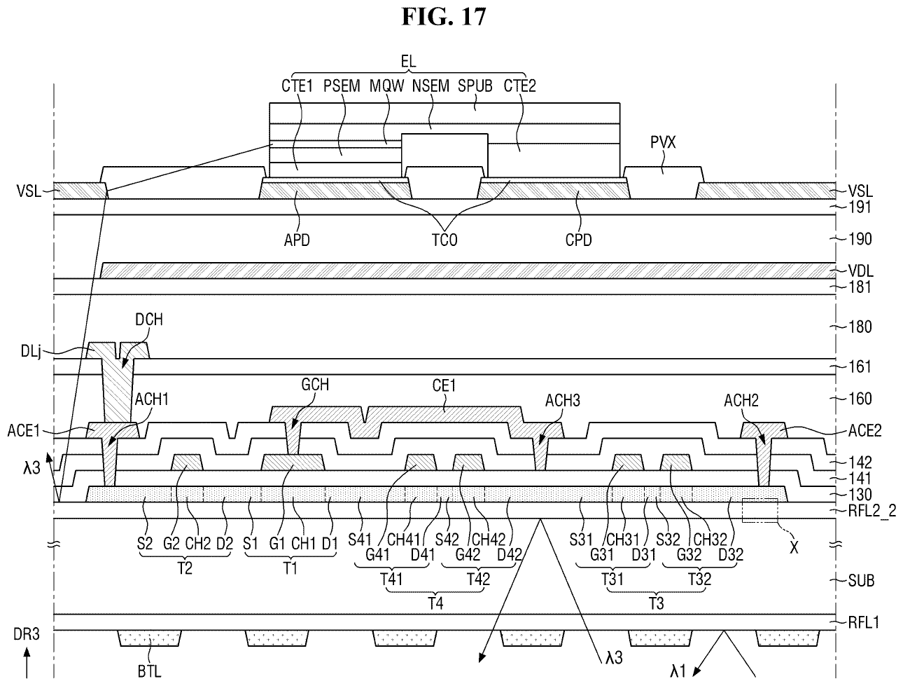

FIG. 17 is a cross-sectional view illustrating an example of the first to fourth transistors of the first sub-pixel according to one or more embodiments.

Referring to FIG. 17, a second selective reflective film RFL2_2 may be disposed on the first surface of the substrate SUB. The first surface of the substrate SUB may be the front surface of the substrate SUB, and the second surface of the substrate SUB may be the rear surface of the substrate SUB.

The active layer may be disposed on the second selective reflective film RFL2_2. The second selective reflective film RFL2_2 may be designed to mainly reflect light A3 of the third wavelength emitted from the light emitting element EL.

The target reflection wavelength of the second selective reflective film RFL2_2 may be different from the target reflection wavelength of the first selective reflective film RFL1. Specifically, the target reflection wavelength of the second selective reflective film RFL2_2 may be greater than the target reflection wavelength of the first selective reflective film RFL1.

The target reflection wavelength to be reflected by the second selective reflective film RFL2_2 may be a main peak wavelength of light emitted from the light emitting element EL having the lowest luminous efficiency. For example, the target reflection wavelength of the second selective reflective film RFL2_2 may be approximately 650 nm, which is a main peak wavelength of light in a red wavelength band emitted by the light emitting element EL of the first sub-pixel SP1.

Alternatively, the target reflection wavelength of the second selective reflective film RFL2_2 may be approximately 520 nm, which is a main peak wavelength of light in a green wavelength band emitted by the light emitting element EL of the second sub-pixel SP2. Alternatively, the target reflection wavelength of the second selective reflective film RFL2_2 may be approximately 420 nm, which is a main peak wavelength of light in a blue wavelength band emitted by the light emitting element EL of the second sub-pixel SP2.

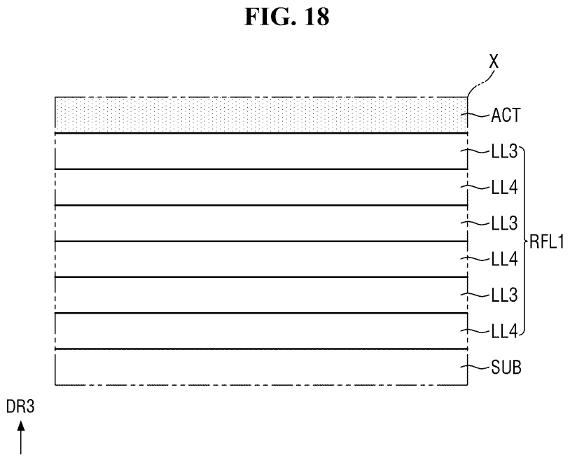

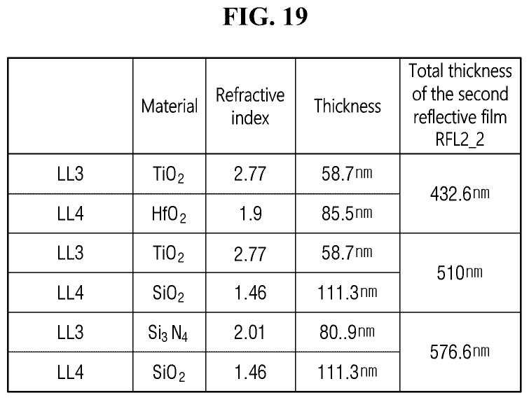

FIG. 18 is an enlarged cross-sectional view illustrating one example of the second selective reflective film of FIG. 17. FIG. 19 is a table showing the third reflective metal layer and the fourth reflective metal layer, and the thickness of the third reflective metal layer and the thickness of the fourth reflective metal layer calculated according to a third target wavelength shown in FIG. 17.

Referring to FIG. 18, the second selective reflective film RFL2_2 may serve as the distributed Bragg reflector. That is, the second selective reflective film RFL2_2 may function as the selective reflective film that reflects light of the third wavelength A3 and transmits light of other wavelengths. To this end, the second selective reflective film RFL2_2 includes N (N is an integer greater than or equal to 2) pairs of third and fourth layers LL3 and LL4. The N third layers LL3 and N fourth layers LL4 may be alternately disposed. In each of the N pairs, the third layer LL3 may be disposed further from the substrate SUB than the fourth layer LL4. For example, three pairs of the third layer LL3 and the fourth layer LL4 of the second selective reflective film RFL2_2 may be disposed in the order of the substrate SUB, the fourth layer LL4, the third layer LL3, the fourth layer LL4, the third layer LL3, the fourth layer LL4, the third layer LL3, and the active layer ACT in the third direction DR3.

Referring to FIG. 19, when the third layer LL3 is TiO₂ and the fourth layer LL4 is HfO₂, the refractive index of the third layer LL3 may be 2.77 and the refractive index of the fourth layer LL4 may be 1.9. A difference between the refractive index of the third layer LL3 and the refractive index of the fourth layer LL4 may be approximately 0.87. When the target reflection wavelength of the second selective reflective film RFL2_2 is 650 nm, the thickness of the third layer LL3 may be approximately 58.7 nm, and the thickness of the fourth layer LL4 may be approximately 85.5 nm. In this case, when the second selective reflective film RFL2_2 includes three pairs of third and fourth layers LL3 and LL4, the total thickness of the second selective reflective film RFL2_2 may be approximately 432.6 nm.

Alternatively, when the third layer LL3 is TiO₂ and the fourth layer LL4 is SiO₂, the refractive index of the third layer LL3 may be 2.77 and the refractive index of the fourth layer LL4 may be 1.46. A difference between the refractive index of the third layer LL3 and the refractive index of the fourth layer LL4 may be approximately 1.31. When the target reflection wavelength of the second selective reflective film RFL2_2 is 650 nm, the thickness of the third layer LL3 may be approximately 58.7 nm, and the thickness of the fourth layer LL4 may be approximately 111.3 nm. In this case, when the second selective reflective film RFL2_2 includes three pairs of third and fourth layers LL3 and LL4, the total thickness of the second selective reflective film RFL2_2 may be approximately 510 nm.

Alternatively, when the third layer LL3 is Si₃N₄ and the second layer LL2 is SiO₂, the third layer LL3 may have a refractive index of 2.01 and the fourth layer LL4 may have a refractive index of 1.46. A difference between the refractive index of the third layer LL3 and the refractive index of the fourth layer LL4 may be approximately 0.55. When the target reflection wavelength of the second selective reflective film RFL2_2 is 650 nm, the thickness of the third layer LL3 may be approximately 80.9 nm, and the thickness of the fourth layer LL4 may be approximately 111.3 nm. In this case, when the second selective reflective film RFL2_2 includes three pairs of third and fourth layers LL3 and LL4, the total thickness of the second selective reflective film RFL2_2 may be approximately 576.6 nm.

As shown in FIGS. 17 to 19, the second selective reflective film RFL2 has the target reflection wavelength corresponding to the main peak wavelength of light emitted from the light emitting element EL. Therefore, because the light traveling downward from the light emitting element EL may be reflected upward and emitted, the light-emitting efficiency of the light emitting element EL may be increased.

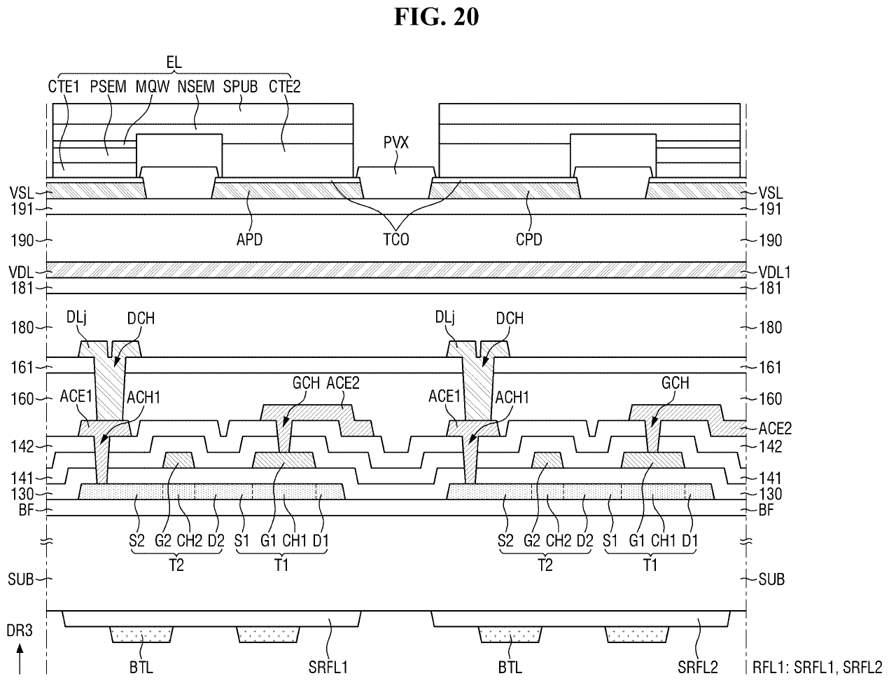

FIG. 20 is a cross-sectional view illustrating one example of the first and second transistors of the first sub-pixel and the first and second transistors of the second sub-pixel, according to one or more embodiments.

Referring to FIG. 20, the first selective reflective film RFL1 includes a plurality of reflective films SRFL1 and SRFL2 disposed apart (e.g., spaced) from each other. Each of the plurality of reflective films SRFL1 and SRFL2 may overlap the first to nineteenth transistors T1 to T19 of each of the sub-pixels SP1, SP2, and SP3.

For example, the first selective reflective film RFL1 may include the first reflective film SRFL1 and the second reflective film SRFL2. The first reflective film SRFL1 may overlap the first to nineteenth transistors T1 to T19 of the first sub-pixel SP1 in the third direction DR3. The second reflective film SRFL2 may overlap the first to nineteenth transistors T1 to T19 of the second sub-pixel SP2 in the third direction DR3. Because the first reflective film SRFL1 and the second reflective film SRFL2 are spaced from each other, a gap may exist between the first reflective film SRFL1 and the second reflective film SRFL2.

Because each of the first reflective film SRFL1 and the second reflective film SRFL2 illustrated in FIG. 20 may be substantially the same as the first selective reflective film RFL1 described in connection with FIGS. 7 and 8, descriptions of the first reflective film SRFL1 and the second reflective film SRFL2 are omitted.

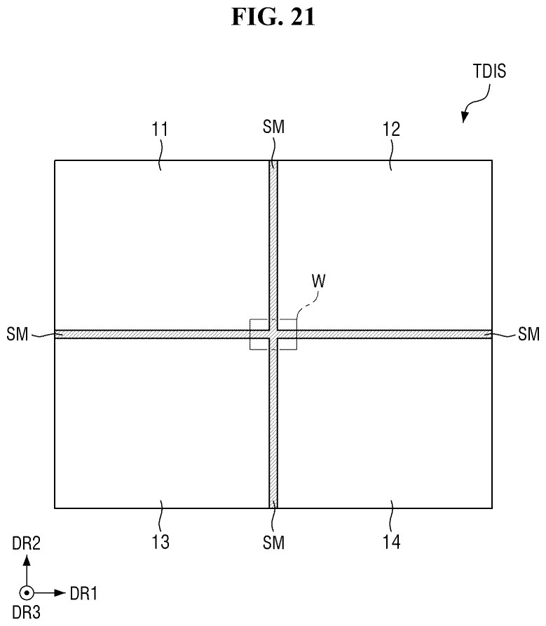

FIG. 21 is a perspective view illustrating a tiled display device including a plurality of display devices according to one or more embodiments.

Referring to FIG. 21, a tiled display device TDIS may include a plurality of display devices 11, 12, 13, and 14, and a connection member SM. The plurality of display devices 11, 12, 13, and 14 may be arranged in a matrix form in M (M is a positive integer) number of rows and N (N is a positive integer) number of columns. For example, the tiled display device TDIS may include a first display device 11, a second display device 12, a third display device 13, and a fourth display device 14.

The first display device 11 and the second display device 12 may be adjacent to each other in the first direction DR1. The first display device 11 and the third display device 13 may be adjacent to each other in the second direction DR2. The third display device 13 and the fourth display device 14 may be adjacent to each other in the first direction DR1. The second display device 12 and the fourth display device 14 may be adjacent to each other in the second direction DR2.

However, the number and arrangement of the plurality of display devices 11, 12, 13, and 14 in the tiled display device TDIS are not limited to those illustrated in FIG. 21. The number and arrangement of the display devices 11, 12, 13, and 14 in the tiled display device TDIS may be determined in response to the size of the display device 10 and the tiled display device TDIS, and the shape of the tiled display device TDIS.

The plurality of display devices 11, 12, 13, and 14 may have the same size as each other, but embodiments of the present disclosure are not limited thereto. For example, the plurality of display devices 11, 12, 13, and 14 may have different sizes.

Each of the plurality of display devices 11, 12, 13, and 14 may have a rectangular shape including long sides and short sides. The plurality of display devices 11, 12, 13, and 14 may be disposed such that the long sides or the short sides thereof are connected to each other. Some or all of the plurality of display devices 11, 12, 13, and 14 may be disposed at the edge of the tiled display device TDIS and may be disposed one side of the tiled display device TDIS. At least one of the plurality of display devices 11, 12, 13, and 14 may be disposed at least one corner of the tiled display device TDIS and may be formed two adjacent sides of the tiled display device TDIS. At least one of the plurality of display devices 11, 12, 13, and 14 may be surrounded by other display devices.

Each of the plurality of display devices 11, 12, 13, and 14 may be substantially the same as the display device 10 described with reference to FIGS. 1 and 2. Therefore, a description of each of the plurality of display devices 11, 12, 13, and 14 will be omitted.

The connection member SM may include a coupling member or an adhesive member. In this case, the plurality of display devices 11, 12, 13, and 14 may be connected to each other by the coupling member or the adhesive member of the connection member SM. The connection member SM may be disposed between the first display device 11 and the second display device 12, between the first display device 11 and the third display device 13, between the second display device 12 and the fourth display device 14, and between the third display device 13 and the fourth display device 14.

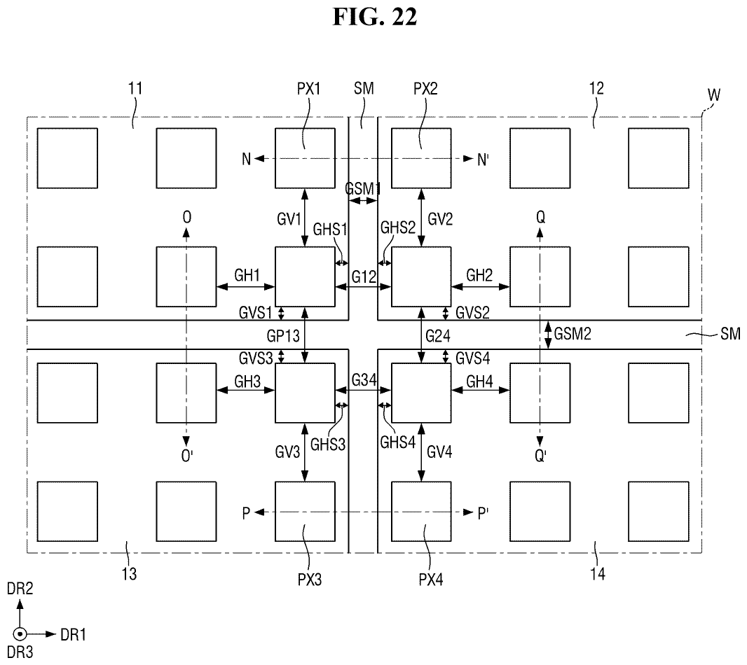

FIG. 22 is an enlarged layout view illustrating a region W of FIG. 21 in detail.

Referring to FIG. 22, the connection member SM may have a planar shape of a cross, or a plus sign in a central area of the device TDIS in which the first display device 11, the second display device 12, the third display device 13, and the fourth display device 14 are adjacent to each other. The connection member SM may be disposed between the first display device 11 and the second display device 12, between the first display device 11 and the third display device 13, between the second display device 12 and the fourth display device 14, and between the third display device 13 and the fourth display device 14.

The first display device 11 may include first pixels PX1 arranged in a matrix form in the first direction DR1 and the second direction DR2 to display an image. The second display device 12 may include second pixels PX2 arranged in a matrix in the first direction DR1 and the second direction DR2 to display an image. The third display device 13 may include third pixels PX3 arranged in a matrix in the first direction DR1 and the second direction DR2 to display an image. The fourth display device 14 may include fourth pixels PX4 arranged in a matrix in the first direction DR1 and the second direction DR2 to display an image.

A minimum distance between the first pixels PX1 adjacent in the first direction DR1 may be defined as a first horizontal separation distance GH1, and a minimum distance between the second pixels PX2 adjacent in the first direction DR1 may be defined as a second horizontal separation distance GH2. The first horizontal separation distance GH1 and the second horizontal separation distance GH2 may be substantially the same.

The connection member SM may be disposed between the first pixel PX1 and the second pixel PX2 adjacent in the first direction DR1. A minimum distance G12 between the first pixels PX1 and the second pixels PX2 adjacent in the first direction DR1 may be the sum of the minimum distance GHS1 between the first pixel PX1 and the connection member SM in the first direction DR1, the minimum distance GHS2 between the second pixel PX2 and the connection member SM in the first direction DR1 and a width GSM1 of the connection member SM in the first direction DR1.

The minimum distance G12 between the first pixel PX1 and the second pixel PX2 adjacent in the first direction DR1, the first horizontal separation distance GH1, and the second horizontal separation distance GH2 may be substantially the same. To this end, the minimum distance GHS1 between the first pixel PX1 and the connection member SM in the first direction DR1 may be smaller than the first horizontal separation distance GH1, and the minimum distance GHS2 between the second pixel PX2 and the connection member SM in the first direction DR1 may be smaller than the second horizontal separation distance GH2. Further, the width GSM1 of the connection member SM in the first direction DR1 may be smaller than the first horizontal separation distance GH1 or the second horizontal separation distance GH2.

A minimum distance between the third pixels PX3 adjacent in the first direction DR1 may be defined as a third horizontal separation distance GH3, and a minimum distance between the fourth pixels PX4 adjacent in the first direction DR1 may be defined as a fourth horizontal separation distance GH4. The third horizontal separation distance GH3 and the fourth horizontal separation distance GH4 may be substantially the same.

The connection member SM may be disposed between the third pixel PX3 and the fourth pixel PX4 adjacent in the first direction DR1. A minimum distance G34 between the third pixel PX3 and the fourth pixel PX4 adjacent in the first direction DR1 may be the sum of a minimum distance GHS3 between the third pixel PX3 and the connection member SM in the first direction DR1, a minimum distance GHS4 between the fourth pixel PX4 and the connection member SM in the first direction DR1, and the width GSM1 of the connection member SM in the first direction DR1.

The minimum distance G34 between the third pixel PX3 and the fourth pixel PX4 adjacent in the first direction DR1, the third horizontal separation distance GH3, and the fourth horizontal separation distance GH4 may be substantially the same. To this end, the minimum distance GHS3 between the third pixel PX3 and the connection member SM in the first direction DR1 may be smaller than the third horizontal separation distance GH3, and the minimum distance GHS4 between the fourth pixel PX4 and the connection member SM in the first direction DR1 may be smaller than the fourth horizontal separation distance GH4. Further, in the first direction DR1, the width GSM1 of the connection member SM may be smaller than the third horizontal separation distance GH3 or the fourth horizontal separation distance GH4.

The minimum distance between the first pixels PX1 adjacent in the second direction DR2 may be defined as a first vertical separation distance GV1, and the minimum distance between the third pixels PX3 adjacent in the second direction DR2 may be defined as a third vertical separation distance GV3. The first vertical separation distance GV1 and the third vertical separation distance GV3 may be substantially the same.

The connection member SM may be disposed between the first pixel PX1 and the third pixel PX3 adjacent in the second direction DR2. A minimum distance GP13 between the first pixel PX1 and the third pixel PX3 adjacent in the second direction DR2 may be the sum of a minimum distance GVS1 between the first pixel PX1 and the connection member SM in the second direction DR2, a minimum distance GVS3 between the third pixel PX3 and the connection member SM in the second direction DR2, and a width GSM2 of the connection member SM in the second direction DR2.

The minimum distance GP13 between the first pixel PX1 and the third pixel PX3 adjacent in the second direction DR2, the first vertical separation distance GV1, and the third vertical separation distance GV3 may be substantially the same.

To this end, the minimum distance GVS1 between the first pixel PX1 and the connection member SM in the second direction DR2 may be smaller than the first vertical separation distance GV1, and the minimum distance GVS3 between the third pixel PX3 and the connection member SM in the second direction DR2 may be smaller than the third vertical separation distance GV3. Further, in the second direction DR2, the width GSM2 of the connection member SM may be smaller than the first vertical separation distance GV1 or the third vertical separation distance GV3.

The minimum distance between the adjacent second pixels PX2 in the second direction DR2 may be defined as a second vertical separation distance GV2, and the minimum distance between the fourth pixels PX4 adjacent in the second direction DR2 may be defined as a fourth vertical separation distance GV4. The second vertical separation distance GV2 and the fourth vertical separation distance GV4 may be substantially the same.

The connection member SM may be disposed between the second pixel PX2 and the fourth pixel PX4 adjacent in the second direction DR2. The minimum distance G24 between the second pixel PX2 and the fourth pixel PX4 adjacent in the second direction DR2 may be the sum of the minimum distance GVS2 between the second pixel PX2 and the connection member SM in the second direction DR2, the minimum distance GVS4 between the fourth pixel PX4 and the joint SM in the second direction DR2, and the width GSM2 of the connection member SM in the second direction DR2.

A minimum distance G24 between the second pixel PX2 and the fourth pixel PX4 adjacent in the second direction DR2, a second vertical separation distance GV2, and a fourth vertical separation distance GV4 may be substantially the same. To this end, a minimum distance GVS2 between the second pixel PX2 and the connection member SM in the second direction DR2 may be smaller than the second vertical separation distance GV2, and a minimum distance GVS4 between the fourth pixel PX4 and the connection member SM in the second direction DR2 may be smaller than the fourth vertical separation distance GV4. Further, in the second direction DR2, the width GSM2 of the connection member SM may be smaller than the second vertical separation distance GV2 or the fourth vertical separation distance GV4.

As shown FIGS. 22, the minimum distance between pixels of adjacent display devices may be substantially equal to the minimum distance between each of the pixels to prevent the connection member SM from being recognized between images displayed by the plurality of display devices 11, 12, 13, and 14.

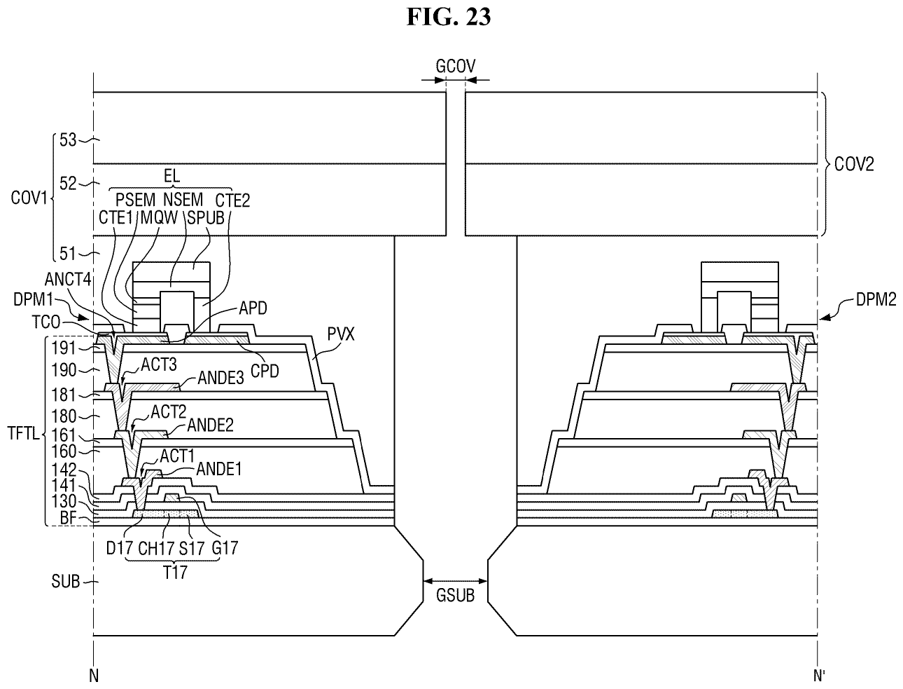

FIG. 23 is a cross-sectional view illustrating an example of a tiled display device taken along the line N-N′ of FIG. 22.

Referring to FIG. 23, the first display device 11 includes a first display module DPM1 and a first front cover COV1. The second display device 12 includes a second display module DPM2 and a second front cover COV2.

Each of the first display module DPM1 and the second display module DPM2 includes a substrate SUB, a thin film transistor layer TFTL, and light emitting elements EL.

The display panel 100 may include the thin film transistor layer TFTL and the light emitting elements EL disposed on the substrate SUB. The thin film transistor layer TFTL may be a layer in which thin film transistors TFT are formed. The thin film transistors may include the first to nineteenth transistors T1 to T19 shown in FIG. 5.

The thin film transistor layer TFTL includes the active layer, the first gate metal layer, the second gate metal layer, the first source metal layer, a second source metal layer, a third source metal layer, a fourth source metal layer, and a transparent metal layer TCO. The thin film transistor layer TFTL also includes the buffer film BF, the gate insulating film 130, the first interlayer insulating film 141, the second interlayer insulating film 142, a first planarization film 160, a first inorganic insulating film 161, a second planarization film 180, a second inorganic insulating film 181, a third planarization film 190, a third inorganic insulating film 191, and a protective film PVX1.

Because the thin film transistor layer TFTL has already been described above with reference to FIG. 7, redundant description will be omitted.

The first source metal layer may further include a first anode connection electrode ANDE1. The first anode connection electrode ANDE1 may be connected to a seventeenth drain electrode D17 of the seventeenth transistor T17 through a first anode contact hole ACT1 penetrating the gate insulating film 130, the first interlayer insulating film 141, and the second interlayer insulating film 142.

The second source metal layer may include a second anode connection electrode ANDE2. The second anode connection electrode ANDE2 may be connected to the first anode connection electrode ANDE1 through a second anode contact hole ACT2 penetrating the first planarization film 160 and the first inorganic insulating film 161.

The third source metal layer DTL3 may further include a third anode connection electrode ANDE3. The third anode connection electrode ANDE3 may be connected to the second anode connection electrode ANDE2 through a third anode contact hole ACT3 penetrating the second planarization film 180 and the second inorganic insulating film 181.

The anode pad electrode APD may be connected to the third anode connection electrode ANDE3 through a fourth anode contact hole ACT4 penetrating the third planarization film 190 and the third inorganic insulating film 191. The cathode electrode CPD may be electrically connected to the third power supply line VSL.

A distance GSUB between the substrate SUB of the first display device 11 and the substrate SUB of the second display device 12 may be greater than a distance GCOV between the first front cover COV1 and the second front cover COV2.

Each of the first front cover COV1 and the second front cover COV2 may include an adhesive member 51, a light transmittance control layer 52 disposed on the adhesive member 51, and an anti-glare layer 53 disposed on the light transmittance control layer 52.

The adhesive member 51 of the first front cover COV1 serves to attach the light emitting element layer EL of the first display module DPM1 and the first front cover COV1. The adhesive member 51 of the second front cover COV2 serves to attach the light emitting element layer of the second display module DPM2 and the second front cover COV2. The adhesive member 51 may be a transparent adhesive member capable of transmitting light. For example, the adhesive member 51 may be an optically clear adhesive film or an optically clear resin.

The anti-glare layer 53 may be designed to diffusely reflect external light to prevent deterioration in visibility of an image by reflecting external light as it is. Accordingly, the contrast ratio of images displayed by the first display device 11 and the second display device 12 may be increased due to the anti-glare layer 53.

A light transmittance adjusting layer 52 may be designed to reduce transmittance of external light or light reflected from the first display module DPM1 and the second display module DPM2. Accordingly, it is possible to prevent the gap GSUB between the substrate SUB of the first display module DPM1 and the substrate SUB of the second display module DPM2 from being recognized from the outside.

The anti-glare layer 53 may be implemented as a polarizing plate, and the light transmittance control layer 52 may be implemented as a phase retardation layer, but the present disclosure is not limited thereto.

Because an example of the tiled display device cut along lines O-O′, P-P′, and Q-Q′ of FIG. 22 is substantially the same as an example of the tiled display device cut along N-N′ described in conjunction with FIG. 23, a description thereof is omitted.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a plurality of transistors on one surface of the substrate;
a plurality of light emitting elements on the plurality of transistors;
a plurality of bottom wirings on a rear surface of the substrate; and
a first selective reflective film between the substrate and the plurality of bottom wirings,
wherein the first selective reflective film comprises M pairs of first layers and second layers, where M is an integer greater than or equal to 2, and
wherein a refractive index of the first layer is higher than a refractive index of the second layer.

2. The display device of claim 1, wherein a reflective target wavelength of the first selective reflective film is 310 nm or less.

3. The display device of claim 1, wherein a difference between a refractive index of the first layer and a refractive index of the second layer is 0.55 or more.

4. The display device of claim 1, wherein the first layer comprises TiO₂, and the second layer comprises SiO₂ or HfO₂.

5. The display device of claim 1, wherein the first layer comprises Si₃N₄ and the second layer comprises SiO₂.

6. The display device of claim 1, wherein a thickness of the first layer is smaller than a thickness of the second layer.

7. The display device of claim 1, further comprising a second selective reflective film between the substrate and the plurality of transistors,
wherein the second selective reflective film comprises N pairs of a third layer and a fourth layer, where N is an integer greater than or equal to 2, and
wherein a refractive index of the third layer is higher than a refractive index of the fourth layer.

8. The display device of claim 7, wherein a reflective target wavelength of the second selective reflective film is 310 nm or less.

9. The display device of claim 7, wherein a reflective target wavelength of the first selective reflective film is substantially the same as a reflective target wavelength of the second selective reflective film.

10. The display device of claim 7, wherein a reflective target wavelength of the second selective reflective film is smaller than a reflective target wavelength of the first selective reflective film.

11. The display device of claim 10, wherein a thickness of the second selective reflective film is smaller than a thickness of the first selective reflective film.

12. The display device of claim 1, further comprising a second selective reflective film between the substrate and the plurality of transistors,
wherein the second selective reflective film comprises N pairs of a third layer and a fourth layer, where N is an integer greater than or equal to 2, and
wherein a refractive index of the third layer is higher than a refractive index of the fourth layer.

13. The display device of claim 12, wherein a reflective target wavelength of the second selective reflective film is greater than a reflective target wavelength of the first selective reflective film.

14. The display device of claim 13, wherein a thickness of the second selective reflective film is greater than a thickness of the first selective reflective film.

15. The display device of claim 13, wherein a thickness of the third layer is greater than a thickness of the first layer, and a thickness of the fourth layer is greater than a thickness of the third layer.

16. The display device of claim 1, further comprising data lines on the one surface of the substrate;
power supply lines on the one surface of the substrate; and
side wirings on a side surface of the substrate, connected to one or more of the bottom wirings and the data lines, and connected to one or more of the bottom wirings and the power supply lines.

17. The display device of claim 1, further comprising a device identifier on the rear surface of the substrate and separated from the bottom wirings.

18. A display device comprising:
a substrate;
a plurality of first transistors of a first sub-pixel and a plurality of second transistors of a second sub-pixel on one surface of the substrate;
a first light emitting element on the plurality of first transistors of the first sub-pixel and a second light emitting element on the plurality of second transistors of the second sub-pixel;
a plurality of bottom wirings on a rear surface of the substrate; and
a first selective reflective film between the substrate and the plurality of bottom wirings,
wherein the first selective reflective film comprises:
a first reflective film overlapping the plurality of first transistors of the first sub-pixel in a thickness direction of the substrate; and
a second reflective film overlapping the plurality of second transistors of the second sub-pixel in the thickness direction of the substrate,
wherein the first reflective film and the second reflective film are spaced from each other.

19. The display device of claim 18, wherein each of the first reflective film and the second reflective film comprises M pairs of first layers and second layers, where M is an integer greater than or equal to 2), and
wherein a refractive index of the first layer is higher than a refractive index of the second layer.

20. A tiled display device comprising:
a plurality of display devices; and
a connection member between the plurality of display devices,
wherein one display device from among the plurality of display devices comprises:
a substrate;
a plurality of transistors on one surface of the substrate;
a plurality of light emitting elements on the plurality of transistors;
a plurality of bottom wirings on a rear surface of the substrate; and
a first selective reflective film between the substrate and the plurality of bottom wirings,
wherein the first selective reflective film comprises M pairs of first layers and second layers, where M is an integer greater than or equal to 2, and
wherein a refractive index of the first layer is higher than a refractive index of the second layer.
